(19) United States
(12) Patent Application Publication
(10) Pub. No.: US 2025/0212490 A1
(43) Pub. Date: Jun. 26, 2025

(54) SEMICONDUCTOR DEVICE

(71) Applicant: SAMSUNG ELECTRONICS CO., LTD., Suwon-si (KR)

(72) Inventors: Pilkwang KIM, Suwon-si (KR); AHYOUNG KIM, Suwon-si (KR); SEUNGHYUN SONG, Suwon-si (KR); YONGHEE PARK, Suwon-si (KR); YOUNG-SEOK SONG, Suwon-si (KR); TAKESHI OKAGAKI, Suwon-si (KR)

(73) Assignee: SAMSUNG ELECTRONICS CO., LTD., Suwon-si (KR)

(21) Appl. No.: 18/791,957

(22) Filed: Aug. 1, 2024

(30) Foreign Application Priority Data
Dec. 22, 2023 (KR) 10-2023-0189935

(51) Int. Cl. H01L 29/49; H01L 21/28; H01L 29/06; H01L 29/423; H01L 29/66; H01L 29/775; H01L 29/786

(52) U.S. Cl. CPC H10D 64/679; H01L 21/28123; H10D 30/014; H10D 30/43; H10D 30/6735; H10D 30/6757; H10D 62/121; H10D 64/017

(57) ABSTRACT

A semiconductor device may include a substrate including an active pattern, a channel pattern on the active pattern, the channel pattern including a plurality of semiconductor patterns, which are vertically stacked to be spaced apart from each other, a source/drain pattern connected to the semiconductor patterns, a gate electrode on the semiconductor patterns, a backbone structure on a side surface of the gate electrode, and a first air gap pattern interposed between the backbone structure and each of the semiconductor patterns. The gate electrode may be extended to face a top surface, a side surface, and a bottom surface of each of the semiconductor patterns, and the first air gap pattern may be provided on an opposite side surface of each of the semiconductor patterns.

### CROSS-REFERENCE TO RELATED APPLICATIONS

This application is based on and claims priority under 35 U.S.C. § 119 to Korean Patent Application No. 10-2023-0189935, filed on Dec. 22, 2023, in the Korean Intellectual Property Office, the entire contents of which are hereby incorporated by reference.

### BACKGROUND

### 1. Field

The disclosure relates to a semiconductor device, and in particular, to a semiconductor device including a field effect transistor.

### 2. Description of Related Art

A semiconductor device includes an integrated circuit including metal-oxide-semiconductor field-effect transistors (MOSFETs). To meet an increasing demand for semiconductor devices with a small pattern size and a reduced design rule, the MOSFETs are being aggressively scaled down. However, scaling down the MOSFETs may lead to deterioration in operational properties of the semiconductor devices. A variety of studies are being conducted to overcome technical limitations associated with the scaling down of the semiconductor device and to realize the semiconductor devices with high performance.

### SUMMARY

Aspects of the disclosure provide a semiconductor device with improved electrical characteristics.

Aspects of the disclosure provide a semiconductor device with an increased integration density.

According to an aspect of the disclosure, there is provided a semiconductor device including: a substrate including an active pattern; a channel pattern on the active pattern, the channel pattern including a plurality of semiconductor patterns vertically stacked and spaced apart from each other; a source/drain pattern connected to the plurality of semiconductor patterns; a gate electrode is provided on a top surface, a first side surface, and a bottom surface of each of the plurality of semiconductor patterns; a backbone structure on a side surface of the gate electrode; and a first air gap pattern between the backbone structure and each of the plurality of semiconductor patterns, wherein the first air gap pattern is provided on a second side surface of each of the plurality of semiconductor patterns.

According to another aspect of the disclosure, there is provided a semiconductor device including: a substrate including a first active pattern and a second active pattern; a first channel pattern on the first active pattern and a second channel pattern on the second active pattern, each of the first channel pattern and second channel pattern including a plurality of semiconductor patterns, which are vertically stacked and spaced apart from each other; a first source/drain pattern connected to the first channel pattern and a second source/drain pattern connected to the second channel pattern; a first gate electrode on the first channel pattern and a second gate electrode on the second channel pattern; and a backbone structure provided between the first gate electrode and the second gate electrode, wherein the backbone structure includes: a liner pattern on a side surface of each of the first gate electrode and the second gate electrode; and a backbone pattern provided in a space defined by the liner pattern, and wherein the liner pattern contacts the plurality of semiconductor patterns.

According to another aspect of the disclosure, there is provided a semiconductor device including: a substrate including a first active pattern and a second active pattern; a device isolation layer defining each of the first active pattern and the second active pattern; a first channel pattern on the first active pattern and a second channel pattern on the second active pattern, each of the first channel pattern and the second channel pattern including a plurality of semiconductor patterns, which are stacked and spaced apart from each other; a first source/drain pattern connected to the first channel pattern and a second source/drain pattern connected to the second channel pattern; a first gate electrode on the first channel pattern and a second gate electrode on the second channel pattern, each of the first gate electrode and the second gate electrode including inner electrodes provided between adjacent ones of the plurality of semiconductor patterns and an outer electrode provided on an uppermost semiconductor pattern among of the plurality of semiconductor patterns; a first backbone structure and a second backbone structure on the device isolation layer, the first backbone structure being provided between the first source/drain pattern and second source/drain pattern, the second backbone structure being provided between the first gate electrode and the second gate electrode; a gate insulating layer interposed between the first gate electrode, the second gate electrode and each of the first channel pattern and second channel pattern; a first air gap pattern provided between the gate insulating layer and the second backbone structure; a gate spacer on a side surface of each of the first gate electrode and the second gate electrode; a gate capping pattern on a top surface of each of the first gate electrode and the second gate electrode; an interlayer insulating layer provided on the first source/drain pattern, the second source/drain pattern and the gate capping pattern; an active contact provided to penetrate the interlayer insulating layer and electrically connected to each of the first source/drain pattern, the second source/drain pattern; a first gate contact provided to penetrate the gate capping pattern on the first gate electrode and the interlayer insulating layer and electrically connected to the first gate electrode; a second gate contact provided to penetrate the gate capping pattern on the second gate electrode and the interlayer insulating layer and electrically connected to the second gate electrode a first metal layer on the interlayer insulating layer, the first metal layer including a first interconnection line electrically connected to the active contact and the first gate contact and the second gate contact; and a second metal layer on the first metal layer, the second metal layer including a second interconnection line electrically connected to the first metal layer, wherein the first backbone structure includes: a first sub-backbone pattern on the device isolation layer; and a second backbone pattern filling a space defined by the first sub-backbone pattern, wherein the second backbone structure includes: a second sub-backbone pattern on the device isolation layer; and the second backbone pattern on the second sub-backbone pattern, wherein an uppermost surface of the first sub-backbone pattern is located higher than an uppermost surface of the second sub-backbone pattern.

### BRIEF DESCRIPTION OF DRAWINGS

FIGS. 1 to 3 are conceptual diagrams illustrating logic cells of a semiconductor device according to an embodiment of the disclosure.

FIG. 4 is a plan view illustrating a semiconductor device according to an embodiment of the disclosure.

FIGS. 5A to 5E are sectional views taken along lines A-A′, B-B′, C-C′, D-D′, and E-E′ of FIG. 4, and FIG. 5F is an enlarged sectional view illustrating a portion ‘M’ of FIG. 5E.

FIG. 6A is a sectional view illustrating another example of the structure of FIG. 5E, and FIG. 6B is an enlarged sectional view illustrating a portion ‘N’ of FIG. 6A.

FIG. 7A is a sectional view illustrating still other example of the structure of FIG. 5E, and FIG. 7B is an enlarged sectional view illustrating a portion ‘O’ of FIG. 7A.

FIGS. 8A to 8C are sectional views illustrating other examples of the structures of FIGS. 5C to 5E, and FIG. 8D is an enlarged sectional view illustrating a portion ‘P’ of FIG. 8C.

FIGS. 9A to 17E are sectional views illustrating a method of fabricating a semiconductor device according to an embodiment of the disclosure.

### DETAILED DESCRIPTION

Example embodiments of the disclosure will now be described more fully with reference to the accompanying drawings, in which example embodiments are shown.

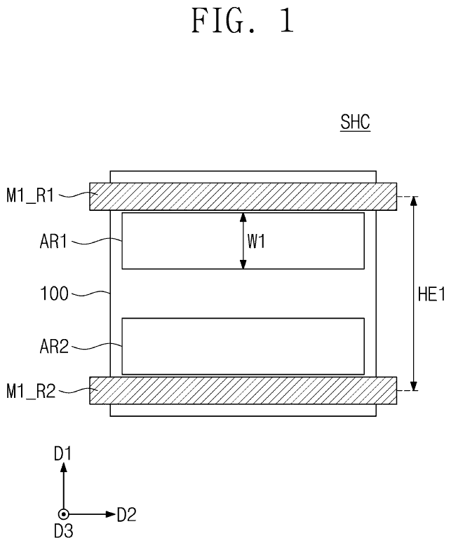

FIGS. 1 to 3 are conceptual diagrams illustrating logic cells of a semiconductor device according to an embodiment of the disclosure.

In FIG. 1, a diagram illustrating a single height cell SHC is provided. According to an embodiment, the single height cell SHC may include a first power line M1_R1 and a second power line M1_R2 may be provided on a substrate 100. The first power line M1_R1 may be a first conduction path of a source voltage VSS (e.g., a ground voltage). That is, the source voltage may be provided on the first power line M1_R1. The second power line M1_R2 may be a second conduction path of a drain voltage VDD (e.g., a power voltage). That is, the drain voltage may be provided on the second power line M1_R2.

The single height cell SHC may be defined between the first power line M1_R1 and the second power line M1_R2. The single height cell SHC may include a first active region AR1 and a second active region AR2. One of the first and second active regions AR1 and AR2 may be a PMOSFET region, and the other of the first and second active regions AR1 and AR2 may be an NMOSFET region. In other words, the single height cell SHC may have a CMOS structure provided between the first and second power lines M1_R1 and M1_R2.

Each of the first and second active regions AR1 and AR2 may have an active width W1 in a first direction D1. A length of the single height cell SHC in the first direction D1 may be defined as a SHC height HE1. The SHC height HE1 may be substantially equal to a distance (e.g., pitch) between the first and second power lines M1_R1 and M1_R2.

The single height cell SHC may constitute a single logic cell. According to one or more embodiments of the disclosure, the logic cell may mean a logic device that is configured to execute a specific function. In other words, the logic cell may include transistors constituting the logic device and interconnection lines connecting the transistors to each other. For example, the logic device may include, but is not limited to an AND device, an OR device, a XOR device, a XNOR device, an inverter, etc.

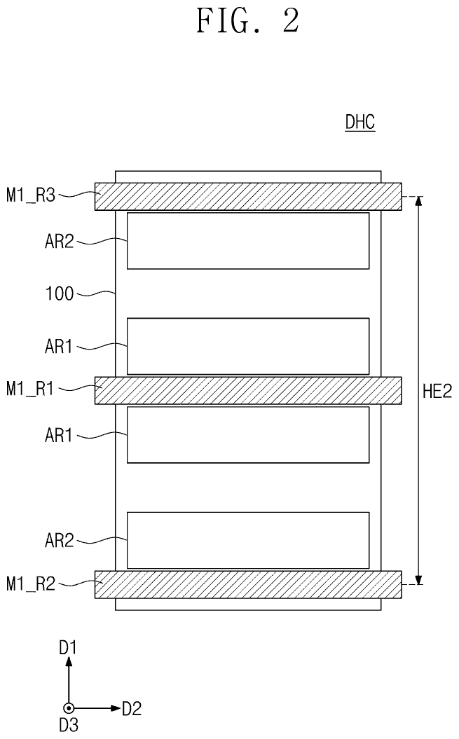

In FIG. 2, a diagram illustrating a double height cell DHC is provided. For example, a first power line M1_R1, a second power line M1_R2, and a third power line M1_R3 may be provided on the substrate 100. The first power line M1_R1 may be provided between the second power line M1_R2 and the third power line M1_R3. The third power line M1_R3 may be a third conduction path of the source voltage VSS. That is, the source voltage may be provided on the third power line M1_R3.

The double height cell DHC may be defined between the second power line M1_R2 and the third power line M1_R3. The double height cell DHC may include two first active regions AR1 and two second active regions AR2.

One of the second active regions AR2 may be adjacent to the second power line M1_R2. The other of the second active regions AR2 may be adjacent to the third power line M1_R3. The two first active regions AR1 may be adjacent to the first power line M1_R1. In a plan view, the first power line M1_R1 may be provided between the two first active regions AR1.

A length of the double height cell DHC in the first direction D1 may be defined as a DHC height HE2. The DHC height HE2 may be about two times the SHC height HE1 of FIG. 1. The two first active regions AR1 of the double height cell DHC may be combined to serve as a single active region.

In an embodiment, the double height cell DHC shown in FIG. 2 may be defined as a multi-height cell. According to an embodiment, the multi-height cell may include a triple height cell. The triple height cell may have a cell height that is about three times the cell height of the single height cell SHC.

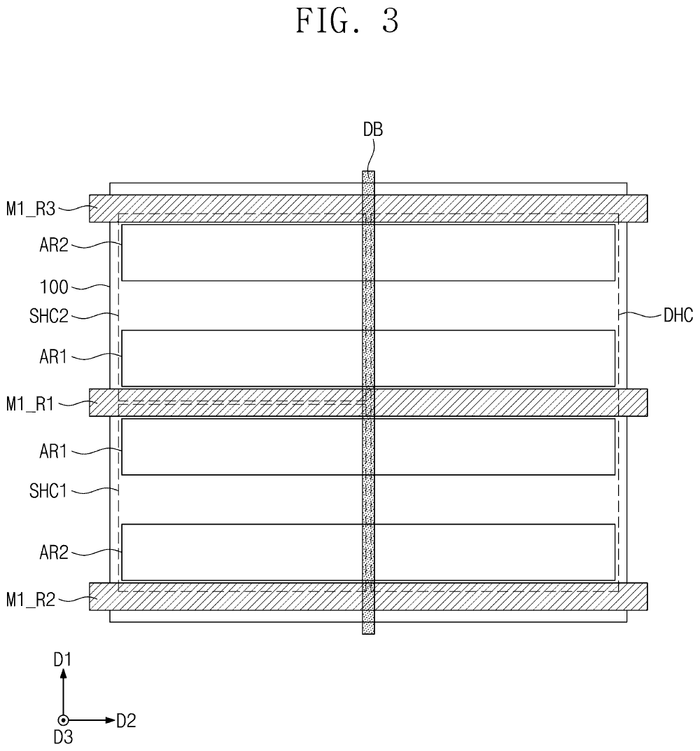

Referring to FIG. 3, a first single height cell SHC1, a second single height cell SHC2, and a double height cell DHC may be two-dimensionally arranged on the substrate 100. The first single height cell SHC1 may be provided between the first and second power lines M1_R1 and M1_R2. The second single height cell SHC2 may be provided between the first and third power lines M1_R1 and M1_R3. The second single height cell SHC2 may be adjacent to the first single height cell SHC1 in the first direction D1.

The double height cell DHC may be provided between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

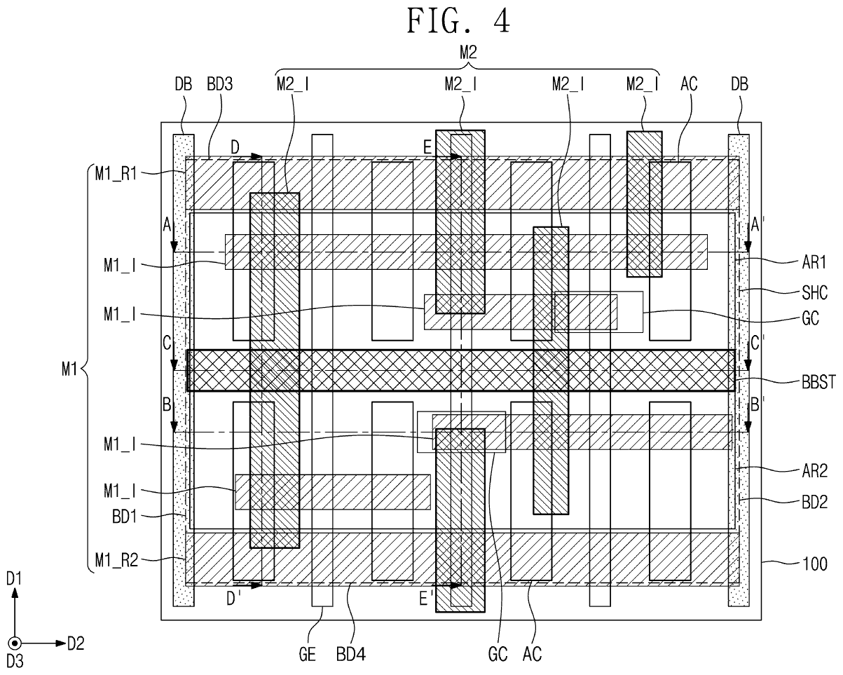

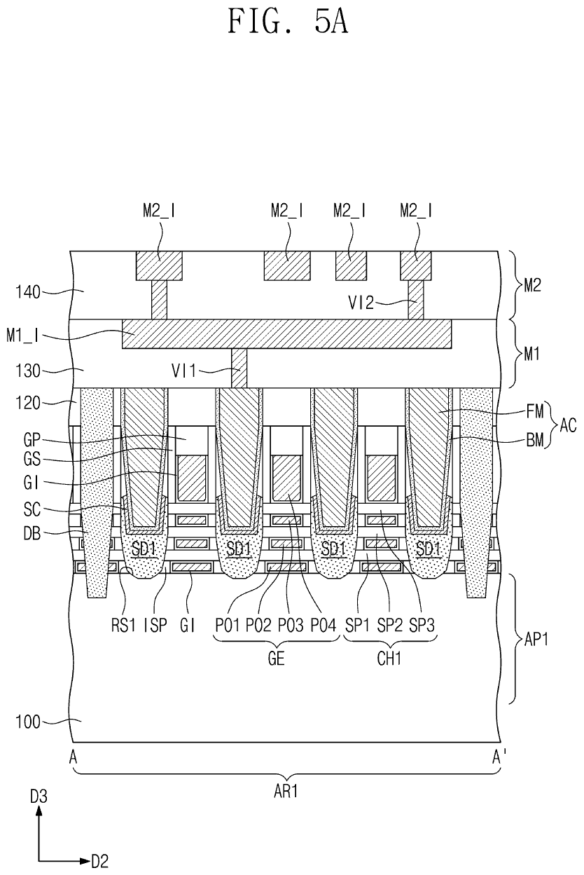

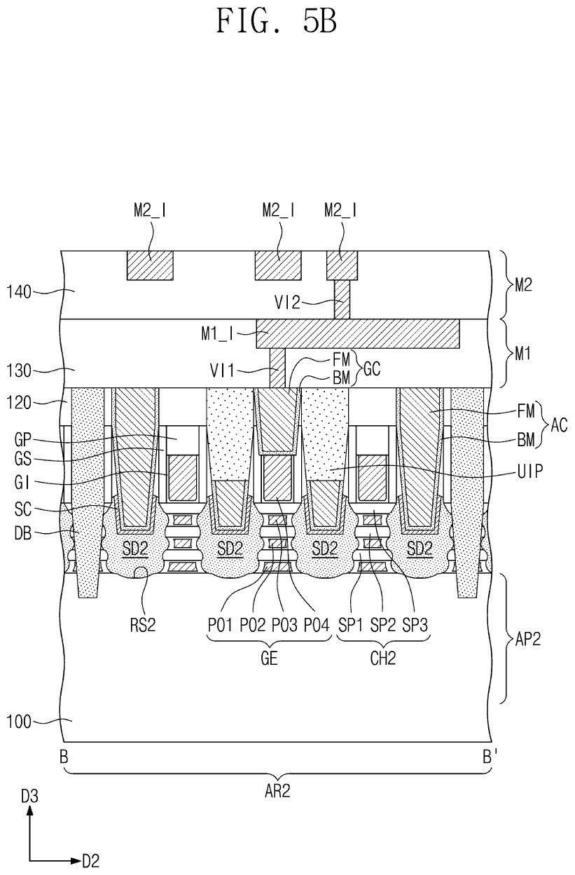

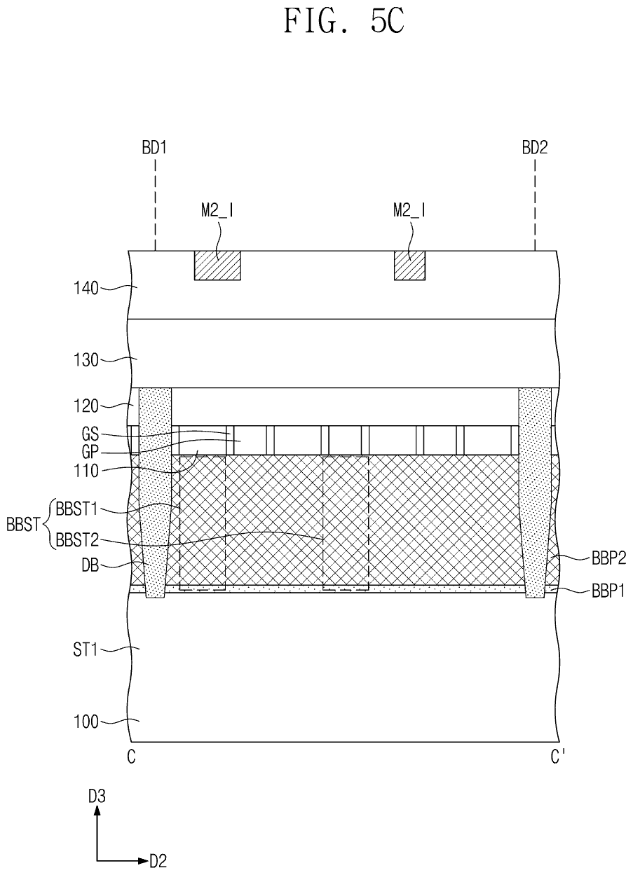

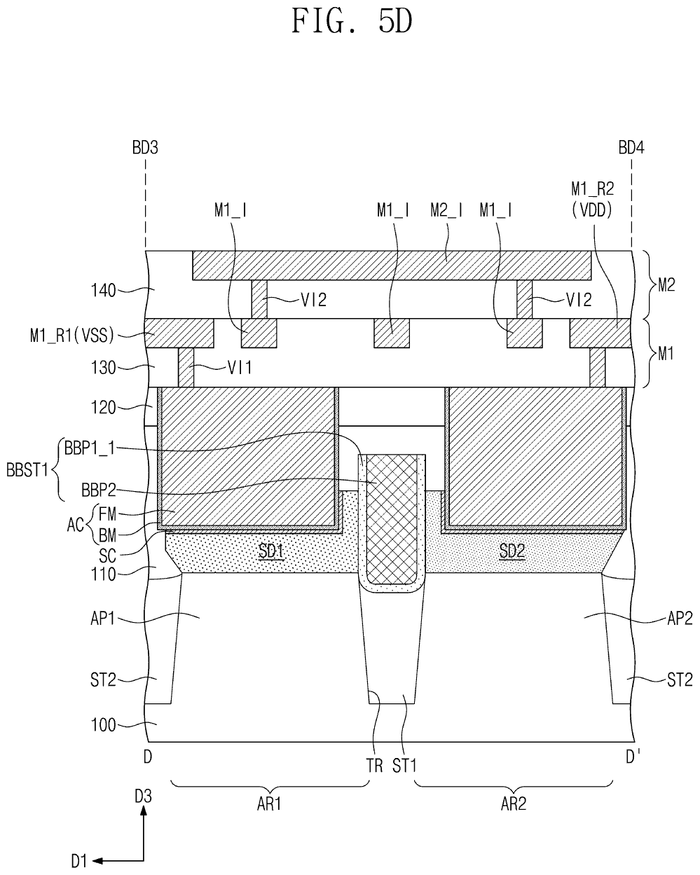

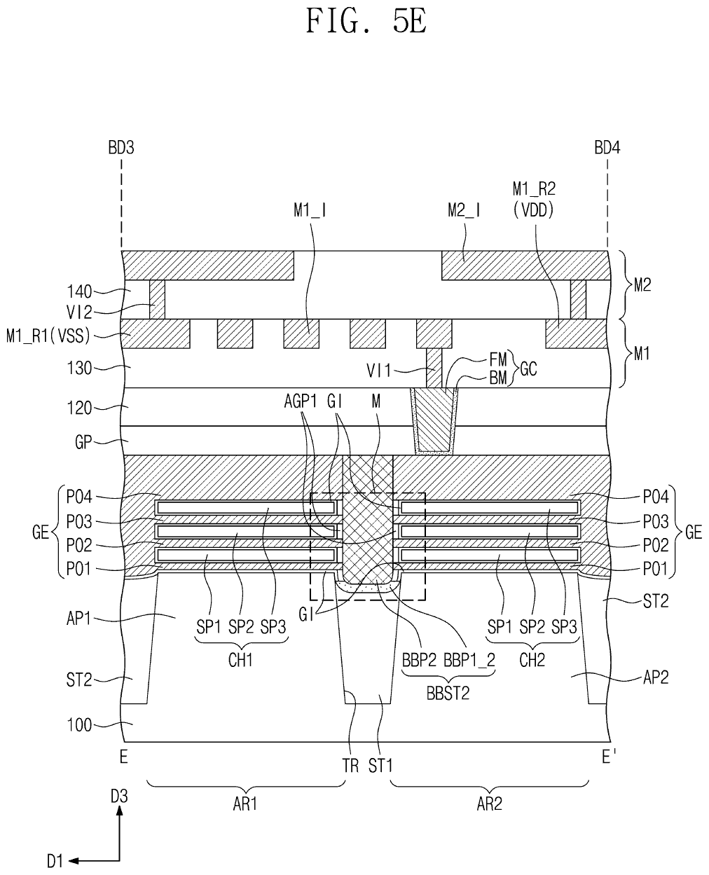

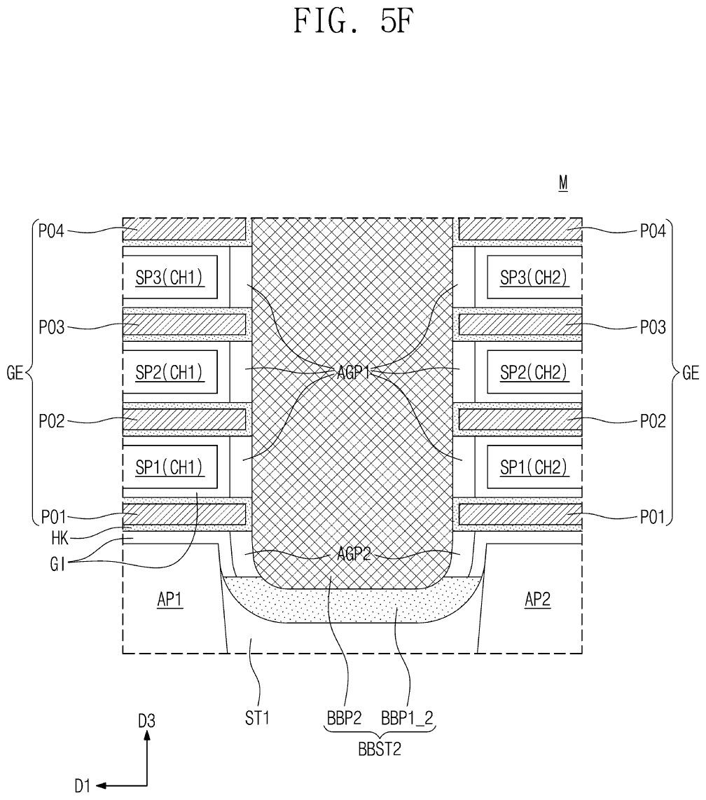

FIG. 4 is a plan view illustrating a semiconductor device according to an embodiment of the disclosure. FIGS. 5A to 5E are sectional views taken along lines A-A′, B-B′, C-C′, D-D′, and E-E′ of FIG. 4. FIG. 5F is an enlarged sectional view illustrating a portion ‘M’ of FIG. 5E. The semiconductor device of FIGS. 4 and 5A to 5F may be a concrete example of the single height cell SHC of FIG. 1.

Referring to FIGS. 4 and 5A to 5E, the single height cell SHC may be provided on the substrate 100. Logic transistors constituting a logic circuit may be provided on the single height cell SHC. The substrate 100 may be a semiconductor substrate. The semiconductor substrate may include, but is not limited to, silicon, germanium, silicon germanium, a compound semiconductor material, or the like. As an example, the substrate 100 may be a silicon substrate. In an embodiment, the substrate 100 may include a silicon-based insulating layer. In other words, the substrate 100 may be an insulating substrate. The insulating substrate may include a silicon oxide layer, a silicon nitride layer, or a silicon oxynitride layer.

The substrate 100 may include the first and second active regions AR1 and AR2. Each of the first and second active regions AR1 and AR2 may be extended in the second direction D2. In an embodiment, the first active region AR1 may be an NMOSFET region, and the second active region AR2 may be a PMOSFET region.

Referring to FIG. 5D, a first active pattern AP1 and a second active pattern AP2 may be defined by a trench TR, which is formed in an upper portion of the substrate 100. The first active pattern AP1 may be provided on the first active region AR1, and the second active pattern AP2 may be provided on the second active region AR2. The first and second active patterns AP1 and AP2 may be extended in the second direction D2. Each of the first and second active patterns AP1 and AP2 may be a vertically protruding portion of the substrate 100.

Device isolation layers ST1 and ST2 may be provided on the substrate 100. The first and second active patterns AP1 and AP2 may be defined by the device isolation layers ST1 and ST2. The device isolation layers ST1 and ST2 may fill the trench TR. For example, a first device isolation layer ST1 may fill the trench TR between the first and second active patterns AP1 and AP2. A second device isolation layer ST2 may be provided to fill the trench TR between the first active patterns AP1 or the trench TR between the second active patterns AP2. The device isolation layers ST1 and ST2 may include a silicon oxide layer. A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3. However, the disclosure is not limited thereto, and as such, each of the first and second channel patterns CH1 and CH2 may include more than three semiconductor patterns or less than three semiconductor patterns. The first semiconductor pattern SP1, the second semiconductor pattern SP2, and the third semiconductor pattern SP3 may be sequentially stacked. The first to third semiconductor patterns SP1, SP2, and SP3 may be spaced apart from each other in a vertical direction (i.e., a third direction D3). The device isolation layers ST1 and ST2 may not be provided on the first and second channel patterns CH1 and CH2. For example, the device isolation layers ST1 and ST2 may not cover the first and second channel patterns CH1 and CH2.

Each of the first to third semiconductor patterns SP1, SP2, and SP3 may include, but is not limited to, at least one of silicon (Si), germanium (Ge), or silicon-germanium (SiGe). For example, each of the first to third semiconductor patterns SP1, SP2, and SP3 may include crystalline silicon. In an embodiment, the first to third semiconductor patterns SP1, SP2, and SP3 may be nanosheets that are stacked. In an embodiment, the first to third semiconductor patterns SP1, SP2, and SP3, which are adjacent to a backbone structure BBST to be described below, may be forksheets that are stacked.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). The first channel pattern CH1 may be provided between a pair of the first source/drain patterns SD1. For example, the first channel pattern CH1 may be interposed between a pair of the first source/drain patterns SD1. That is, each pair of the first source/drain patterns SD1 may be connected to each other by the first to third semiconductor patterns SP1, SP2, and SP3 stacked.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., p-type). The second channel pattern CH2 may be provided between a pair of the second source/drain patterns SD2. For example, the second channel pattern CH2 may be interposed between a pair of the second source/drain patterns SD2. That is, each pair of the second source/drain patterns SD2 may be connected to each other by the first to third semiconductor patterns SP1, SP2, and SP3 stacked.

The first and second source/drain patterns SD1 and SD2 may be epitaxial patterns, which are formed by a selective epitaxial growth (SEG) process. In an embodiment, a top surface of each of the first and second source/drain patterns SD1 and SD2 may be higher than a top surface of the third semiconductor pattern SP3. In another embodiment, at least one of the first and second source/drain patterns SD1 and SD2 may have a top surface that is located at substantially the same level as the top surface of the third semiconductor pattern SP3. For example, one or more of the first and second source/drain patterns SD1 and SD2 may have a different height from each other.

In an embodiment, the first source/drain patterns SD1 may include the same semiconductor element as the substrate 100. For example, the first source/drain patterns SD1 and the substrate 100 may include silicon Si. The second source/drain patterns SD2 may include a semiconductor material having a lattice constant greater than that of the substrate 100. For example, the second source/drain patterns SD2 may include silicon-germanium SiGe. In this case, the pair of the second source/drain patterns SD2 may exert a compressive stress on the second channel pattern CH2 provided between the pair of the second source/drain patterns SD2.

Each of the second source/drain patterns SD2 may include a buffer layer and a main layer on the buffer layer. A volume of the main layer may be larger than a volume of the buffer layer. Each of the buffer and main layers may include silicon-germanium (SiGe). For example, the buffer layer may contain germanium (Ge) of a relatively low concentration. For example, the concentration of germanium (Ge) in the buffer layer may be lower than a first reference value. In another embodiment, the buffer layer may include only silicon (Si), without germanium (Ge). The germanium concentration of the buffer layer may range from 0 at % to 30 at %.

The main layer may contain germanium (Ge) of a relatively high concentration. For example, the concentration of germanium (Ge) in the main layer may be higher than a second reference value. In an embodiment, the germanium concentration of the main layer may range from 30 at % to 70 at %. The germanium concentration of the main layer may increase as a height in the third direction D3 increases. For example, the main layer adjacent to the buffer layer may have a germanium concentration of about 40 at %, and an upper portion of the main layer may have a germanium concentration of about 60 at %.

Each of the buffer and main layers may contain an impurity that allows the second source/drain pattern SD2 to have a p-type conductivity. The impurity may include, but is not limited to, e.g., boron, gallium, or indium. The impurity concentration of each of the buffer and main layers may range from 1E18 atom/cm³ to 5E22 atom/cm³. The impurity concentration of the main layer may be higher than the impurity concentration of the buffer layer.

The buffer layer may be used to protect the main layer in a subsequent process of replacing sacrificial layers SAL with a first inner electrode PO1, a second inner electrode PO2, and a third inner electrode PO3 of a gate electrode GE. That is, the buffer layer may prevent an etchant material, which is used to remove the sacrificial layers SAL, from entering and etching the main layer.

Each of the first source/drain patterns SD1 may include silicon (Si). The first source/drain pattern SD1 may further include impurities that allow the first source/drain pattern SD1 to have a n-type conductivity. The impurities may include, but is not limited to, phosphorus, arsenic, or antimony. The impurity concentration of the first source/drain pattern SD1 may range from 1E18 atom/cm³ to 5E22 atom/cm³.

In an embodiment, the second source/drain pattern SD2 may have an uneven or embossing side surface. That is, the side surface of the second source/drain pattern SD2 may have a wavy profile. The side surface of the second source/drain pattern SD2 may protrude toward the first to third inner electrodes PO1, PO2, and PO3 of the gate electrode GE.

The gate electrodes GE may be provided on the first and second channel patterns CH1 and CH2. Each of the gate electrodes GE may be extended in the first direction D1 to cross the first and second channel patterns CH1 and CH2. Each of the gate electrodes GE may be vertically overlapped with the first and second channel patterns CH1 and CH2. The gate electrodes GE may be arranged at a first pitch in the second direction D2.

The gate electrode GE may include the first inner electrode PO1 interposed between each of the first and second active patterns AP1 and AP2 and the first semiconductor pattern SP1, the second inner electrode PO2 interposed between the first semiconductor pattern SP1 and the second semiconductor pattern SP2, the third inner electrode PO3 interposed between the second semiconductor pattern SP2 and the third semiconductor pattern SP3, and an outer electrode PO4 on the third semiconductor pattern SP3.

Referring to FIG. 5E, the gate electrode GE may be provided on top, bottom, and side surfaces of each of the first to third semiconductor patterns SP1, SP2, and SP3. That is, according to an embodiment, the transistor may be a three-dimensional field effect transistor (e.g., MBCFET or GAAFET) in which the gate electrode GE is provided to three-dimensionally surround the channel pattern. More specifically, according to an embodiment, the transistor may be a three-dimensional field effect transistor in which the gate electrode GE is extended to face three surfaces (e.g., a top surface, a bottom surface and one side surface) of each of the first to third semiconductor patterns SP1, SP2, and SP3.

On the first active region AR1, inner spacers ISP may be respectively interposed between the first to third inner electrodes PO1, PO2, and PO3 of the gate electrode GE and the first source/drain pattern SD1. Each of the first to third inner electrodes PO1, PO2, and PO3 of the gate electrode GE may be spaced apart from the first source/drain pattern SD1, with the inner spacer ISP interposed between the gate electrode GE and the first source/drain pattern SD1. The inner spacer ISP may prevent a leakage current from the gate electrode GE.

Referring back to FIGS. 4 and 5A to 5E, a pair of gate spacers GS may be respectively provided on opposite side surfaces of the outer electrode PO4 of the gate electrode GE. The gate spacers GS may be extended along the outer electrode PO4 of the gate electrode GE and in the first direction D1. Top surfaces of the gate spacers GS may be coplanar with a top surface of the outer electrode PO4 of the gate electrode GE. In an embodiment, the gate spacers GS may include, but is not limited to, at least one of SiCN, SiCON, or SiN. In another embodiment, the gate spacers GS may be a multi-layered structure. For example, a multi-layered gate spacer GS may include at least two different materials selected from SiCN, SiCON, and SiN.

Referring back to FIGS. 4 and 5A to 5D, a gate capping pattern GP may be provided on the gate electrode GE. The gate capping pattern GP may be extended along the gate electrode GE or in the first direction D1. The gate capping pattern GP may include a material having an etch selectivity with respect to first and second interlayer insulating layers 110 and 120, which will be described below. Here, the etch selectivity may be the ratio of etch rates between materials. For example, the gate capping pattern GP may include, but is not limited to, at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover top surface, bottom surface, and opposite side surfaces of each of the first to third semiconductor patterns SP1, SP2, and SP3. The gate insulating layer GI may cover a top surface of the second device isolation layer ST2 below the gate electrode GE.

In an embodiment, the gate insulating layer GI may include, but is not limited to, a silicon oxide layer, a silicon oxynitride layer, and/or a high-k dielectric layer. For example, the gate insulating layer GI may have a structure, in which a silicon oxide layer and a high-k dielectric layer are stacked. The high-k dielectric layer may include, but is not limited to, at least one of high-k dielectric materials having dielectric constants higher than the dielectric constant of silicon oxide. For example, the high-k dielectric material may include, but is not limited to, at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In another embodiment, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In an example case in which two or more capacitors are connected in series and each capacitor has a positive capacitance, a total capacitance may be reduced to a value that is less than a capacitance of each of the capacitors. On the other hand, in another example case in which at least one of serially-connected capacitors has a negative capacitance, a total capacitance of the serially-connected capacitors may have a positive value and may be greater than an absolute value of each capacitance.

In an example case in which a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at the room temperature.

The ferroelectric layer may have the ferroelectric property. The ferroelectric layer may include, but is not limited to, at least one of hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). In another example, the hafnium zirconium oxide may be a compound composed of hafnium (Hf), zirconium (Zr), and/or oxygen (O).

The ferroelectric layer may further include dopants. The dopants may include, but is not limited to, at least one of, for example, aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The kind of the dopants in the ferroelectric layer may vary depending on a ferroelectric material included in the ferroelectric layer.

In an example case in which the ferroelectric layer includes hafnium oxide, the dopants in the ferroelectric layer may include at least one of, for example, gadolinium (Gd), silicon (Si), zirconium (Zr), aluminum (Al), and/or yttrium (Y).

In an example case in which the dopants are aluminum (Al), a content of aluminum in the ferroelectric layer may range from 3 to 8 at % (atomic percentage). Here, the content of the dopants (e.g., aluminum atoms) may be a ratio of the number of aluminum atoms to the number of hafnium and aluminum atoms.

In an example case in which the dopants are silicon (Si), a content of silicon in the ferroelectric layer may range from 2 at % to 10 at %. In an example case in which the dopants are yttrium (Y), a content of yttrium in the ferroelectric layer may range from 2 at % to 10 at %. In an example case in which the dopants are gadolinium (Gd), a content of gadolinium in the ferroelectric layer may range from 1 at % to 7 at %. In an example case in which the dopants are zirconium (Zr), a content of zirconium in the ferroelectric layer may range from 50 at % to 80 at %.

The paraelectric layer may have the paraelectric property. The paraelectric layer may be formed of or include at least one of, for example, silicon oxide and/or high-k metal oxides. The metal oxides, which can be used as the paraelectric layer, may include at least one of, for example, hafnium oxide, zirconium oxide, and/or aluminum oxide, but the disclosure is not limited to these examples.

The ferroelectric layer and the paraelectric layer may be formed of or include the same material. The ferroelectric layer may have the ferroelectric property, but the paraelectric layer may not have the ferroelectric property. In an example case in which the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric property. For example, based on the thickness of the ferroelectric layer satisfying a specific range, the ferroelectric layer may exhibit the ferroelectric property. In an embodiment, the ferroelectric layer may have a thickness ranging from 0.5 to 10 nm, but the disclosure is not limited to this example. As such, according to another embodiment, the ferroelectric layer may have a different thickness range. Since a critical thickness associated with the occurrence of the ferroelectric property varies depending on the kind of the ferroelectric material, the thickness of the ferroelectric layer may be changed depending on the kind of the ferroelectric material. In an example case in which the thickness does not satisfy the specific range, the ferroelectric layer may not exhibit the ferroelectric property.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

Referring back to FIGS. 4 and 5A to 5E, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material. The metallic material may include, but is not limited to, titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may include a metallic material having a resistance lower than a resistance of the first metal pattern. For example, the second metal pattern may include at least one metallic material, which is selected from a group including tungsten (W), aluminum (Al), titanium (Ti), and tantalum (Ta). In an embodiment, the outer electrode PO4 of the gate electrode GE may include the first metal pattern and the second metal pattern on the first metal pattern.

Referring back to FIGS. 4 and 5C to 5E, the backbone structure BBST may be provided on the first device isolation layer ST1. That is, the backbone structure BBST may be vertically overlapped with the first device isolation layer ST1. The backbone structure BBST may be provided on the substrate 100 and between the first and second active regions AR1 and AR2. For example, the backbone structure BBST may be provided between the first active pattern AP1 and the second active pattern AP2. The backbone structure BBST may be extended in the second direction D2. In a plan view, the backbone structure BBST may be a bar-shaped pattern extended in the second direction D2.

The backbone structure BBST may include a first backbone structure BBST1 and a second backbone structure BBST2. Each of the first and second backbone structures BBST1 and BBST2 may be defined as a portion of the backbone structure BBST. The first backbone structure BBST1 may be interposed between the first and second source/drain patterns SD1 and SD2. The second backbone structure BBST2 may be interposed between the gate electrodes GE.

Referring to FIG. 5C, each of the first and second backbone structures BBST1 and BBST2 may include a first backbone pattern BBP1 and a second backbone pattern BBP2. The first backbone pattern BBP1 may be provided on the first device isolation layer ST1. The first backbone pattern BBP1 may have a constant thickness in the third direction D3. The first backbone pattern BBP1 may include a first sub-backbone pattern BBP1_1 and a second sub-backbone pattern BBP1_2. The second backbone pattern BBP2 may be provided on the first backbone pattern BBP1.

The first and second backbone patterns BBP1 and BBP2 may include insulating materials having different etch rates from each other or have an etch selectivity with respect to each other. For example, the first backbone pattern BBP1 may include silicon oxide, and the second backbone pattern BBP2 may include silicon nitride.

The first backbone structure BBST1 will be described in more detail with reference to FIG. 5D. The first backbone structure BBST1 may be provided on the first device isolation layer ST1 and may be interposed between the first and second source/drain patterns SD1 and SD2. The uppermost surface of the first backbone structure BBST1 may be located at a level that is higher than the uppermost surface of each of the first and second source/drain patterns SD1 and SD2 in the third direction D3.

The first backbone structure BBST1 may include the first sub-backbone pattern BBP1_1 and the second backbone pattern BBP2 on the first sub-backbone pattern BBP1_1. The first sub-backbone pattern BBP1_1 may be in direct contact with the first and second source/drain patterns SD1 and SD2. In other words, the first sub-backbone pattern BBP1_1 may be extended from the side surface of the first source/drain pattern SD1 to the side surface of the second source/drain pattern SD2 via a top surface of the first device isolation layer ST1. However, the disclosure is not limited thereto, and as such, according to another embodiment, another layer may be provided between the first sub-backbone pattern BBP1_1 and the first and second source/drain patterns SD1 and SD2. The first sub-backbone pattern BBP1_1 may have a uniform thickness. The second backbone pattern BBP2 may be provided to fill a space defined by the first sub-backbone pattern BBP1_1. That is, the second backbone pattern BBP2 may be enclosed by the first sub-backbone pattern BBP1_1.

The first sub-backbone pattern BBP1_1 and the second backbone pattern BBP2 may include insulating materials having different etch rates from each other or have an etch selectivity with respect to each other. For example, the first sub-backbone pattern BBP1_1 may include silicon oxide, and the second backbone pattern BBP2 may include silicon nitride.

The second backbone structure BBST2 will be described in more detail with reference to FIG. 5E. The second backbone structure BBST2 may be provided on the first device isolation layer ST1 and may be interposed between the gate electrodes GE. The uppermost surface of the second backbone structure BBST2 may be located at the same level as the uppermost surface of the gate electrodes GE in the third direction D3. That is, the uppermost surface of the second backbone structure BBST2 may be substantially coplanar with the uppermost surface of the gate electrode GE.

The second backbone structure BBST2 may include the second sub-backbone pattern BBP1_2 and the second backbone pattern BBP2 on the second sub-backbone pattern BBP1_2. The second sub-backbone pattern BBP1_2 may be extended from a bottom surface of the second backbone pattern BBP2 to a side surface of the second backbone pattern BBP2. For example, the second sub-backbone pattern BBP1_2 may be extended to cover the bottom surface of the second backbone pattern BBP2 and a portion of the side surface of the second backbone pattern BBP2. The second sub-backbone pattern BBP1_2 may be extended to the gate insulating layer GI covering the active patterns AP1 and AP2. That is, the uppermost surface of the second sub-backbone pattern BBP1_2 may be located at a level, which is lower than the uppermost surface of each of the active patterns AP1 and AP2 in the third direction D3. The uppermost surface of the second sub-backbone pattern BBP1_2 may be located at a level, which is lower than the uppermost surface of the first sub-backbone pattern BBP1_1 in the third direction D3.

The second backbone pattern BBP2 may be in direct contact with the gate electrodes GE. That is, the side surface of the second backbone pattern BBP2 may be in contact with a side surface of each of the gate electrodes GE. However, the disclosure is not limited thereto, and as such, according to another embodiment, another layer may be provided between the second backbone pattern BBP2 and the gate electrodes GE. In the first direction D1, a width of the second backbone pattern BBP2 may be smaller than a width of the second sub-backbone pattern BBP1_2.

The second sub-backbone pattern BBP1_2 and the second backbone pattern BBP2 may include insulating materials having different etch rates from each other or have an etch selectivity with respect to each other. For example, the second sub-backbone pattern BBP1_2 may be formed of or include silicon oxide, and the second backbone pattern BBP2 may be formed of or include silicon nitride.

According to an embodiment, first air gap patterns AGP1 may be interposed between the second backbone structure BBST2 and the semiconductor patterns SP1, SP2, and SP3 of each of the channel patterns CH1 and CH2. For example, the first air gap patterns AGP1 may be provided on a side surface of each of the first to third semiconductor patterns SP1, SP2, and SP3. In this case, the gate electrode GE may be provided on an opposite side surface of each of the first to third semiconductor patterns SP1, SP2, and SP3. According to an embodiment, a second air gap pattern AGP2 may be interposed between the gate insulating layer GI and the second backbone structure BBST2.

The air gap patterns AGP1 and AGP2 adjacent to the second backbone structure BBST2 will be described in more detail with reference to FIGS. 5E and 5F. The gate insulating layer GI may be provided to enclose each of the first to third semiconductor patterns SP1, SP2, and SP3. The gate insulating layer GI may be provided a top surface and a portion of a side surface of each of the active patterns AP1 and AP2. For example, the gate insulating layer GI may cover a top surface and a portion of a side surface of each of the active patterns AP1 and AP2. A high-k dielectric layer HK may be interposed between the gate insulating layer GI and the gate electrode GE. In other words, the second backbone pattern BBP2 may be in direct contact with the high-k dielectric layer HK. According to an embodiment, a high-k dielectric layer HK may have a dielectric constant higher than a reference value.

The first air gap pattern AGP1 may be interposed between the gate insulating layer GI and the second backbone pattern BBP2 of the second backbone structure BBST2. Each of the first air gap patterns AGP1 may be enclosed by the high-k dielectric layer HK, the gate insulating layer GI, and the second backbone pattern BBP2. In other words, the first air gap patterns AGP1 may be an empty space enclosed by the high-k dielectric layer HK, the gate insulating layer GI, and the second backbone pattern BBP2. For example, the first air gap patterns AGP1 may be voids or seams.

The second air gap pattern AGP2 may be interposed between each of the active patterns AP1 and AP2 and the second backbone pattern BBP2. The second air gap patterns AGP2 may be enclosed by the high-k dielectric layer HK on the first inner electrode PO1, the gate insulating layer GI on each of the active patterns AP1 and AP2, the second sub-backbone pattern BBP1_2, and the second backbone pattern BBP2. That is, the second air gap patterns AGP2 may be an empty space that is enclosed by the high-k dielectric layer HK, the gate insulating layer GI, the second sub-backbone pattern BBP1_2, and the second backbone pattern BBP2. For example, the second air gap patterns AGP2 may be voids or seams.

In the semiconductor device according to an embodiment of the disclosure, since the air gap pattern AGP1 is formed between the semiconductor patterns SP1 to SP3 and the backbone structure BBST2, it may be possible to increase the stress exerted on the semiconductor patterns SP1 to SP3. That is, by forming an empty space between the semiconductor patterns SP1-SP3 and the backbone structure BBST2, it may be possible to efficiently control the stress exerted on the channel pattern CH1 or CH2. The stress may increase the mobility of carriers in the channel pattern CH1 or CH2.

In addition, since the air gap pattern AGP1 is a void or a seam, a parasitic capacitance between the semiconductor patterns SP1-SP3 and the backbone structure BBST2 may be reduced by the air gap pattern AGP1.

That is, according to an embodiment of the disclosure, by forming the air gap pattern AGP1, it may be possible to improve the electrical characteristics of the forksheet semiconductor device.

A first interlayer insulating layer 110 may be provided on the substrate 100. The first interlayer insulating layer 110 may cover the gate spacers GS, the first and second source/drain patterns SD1 and SD2, and the first backbone structure BBST1. A top surface of the first interlayer insulating layer 110 may be substantially coplanar with a top surface of the gate capping pattern GP and a top surface of the gate spacer GS. A second interlayer insulating layer 120 may be formed on the first interlayer insulating layer 110. For example, the second interlayer insulating layer 120 may be provided on the gate capping pattern GP. For example, the second interlayer insulating layer 120 may be provided to cover the gate capping pattern GP. A third interlayer insulating layer 130 may be provided on the second interlayer insulating layer 120. A fourth interlayer insulating layer 140 may be provided on the third interlayer insulating layer 130. In an embodiment, each of the first interlayer insulating layer 110, the second interlayer insulating layer 120, the third interlayer insulating layer 130, and the fourth interlayer insulating layer 140 may include a silicon oxide layer.

The single height cell SHC may have a first border BD1 and a second border BD2, which are opposite to each other in the second direction D2. The first and second borders BD1 and BD2 may be extended in the first direction D1. The single height cell SHC may have a third border BD3 and a fourth border BD4, which are opposite to each other in the first direction D1. The third and fourth borders BD3 and BD4 may be extended in the second direction D2.

A pair of division structures DB, which are opposite to each other in the second direction D2, may be provided at both sides of the single height cell SHC. For example, the pair of the division structures DB may be respectively provided on the first and second borders BD1 and BD2 of the single height cell SHC. The division structure DB may be extended in the first direction D1 to be parallel to the gate electrodes GE. A pitch between the division structure DB and the gate electrode GE adjacent thereto may be equal to the first pitch.

The division structure DB may be provided to penetrate the first interlayer insulating layer 110 and may be extended into the first and second active patterns AP1 and AP2. The division structure DB may be provided to penetrate an upper portion of each of the first and second active patterns AP1 and AP2. The division structure DB may electrically separate an active region of the single height cell SHC from an active region of a neighboring cell.

Active contacts AC may be provided to penetrate the first and second interlayer insulating layers 110 and 120 and to be electrically connected to the first and second source/drain patterns SD1 and SD2, respectively. The active contacts AC may be respectively provided at both sides of the gate electrode GE. In a plan view, the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. The active contact AC may be provided on at least a portion of the side surface of the gate spacer GS. For example, the active contact AC may cover at least a portion of the side surface of the gate spacer GS. According to an embodiment, the active contact AC may cover a portion of the top surface of the gate capping pattern GP.

A metal-semiconductor compound layer SC may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may include, but is not limited to, at least one of titanium silicide, tantalum silicide, tungsten silicide, nickel silicide, or cobalt silicide.

Gate contacts GC may be provided to penetrate the second interlayer insulating layer 120 and the gate capping pattern GP and may be electrically connected to the gate electrodes GE, respectively. In a plan view, the gate contacts GC may be respectively overlapped with the first and second active regions AR1 and AR2. As an example, the gate contact GC may be provided on the second active pattern AP2 (e.g., see FIG. 5B).

In an embodiment, referring to FIG. 5B, an upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit issue from occurring between the gate contact GC and the active contact AC.

Each of the active and gate contacts AC and GC may include a conductive pattern FM and a barrier pattern BM. For example, the barrier pattern BM may be provided on a side of the conductive pattern FM. For example, the barrier pattern BM may the conductive pattern FM. For example, the conductive pattern FM may include at least one of metallic materials including, but not limited to, aluminum, copper, tungsten, molybdenum, and cobalt. The barrier pattern BM may be provided to cover side and bottom surfaces of the conductive pattern FM. In an embodiment, the barrier pattern BM may include a metal layer and a metal nitride layer. The metal layer may include, but is not limited to, at least one of titanium, tantalum, tungsten, nickel, cobalt, or platinum. The metal nitride layer may include, but is not limited to, at least one of titanium nitride (TiN), tantalum nitride (TaN), tungsten nitride (WN), nickel nitride (NiN), cobalt nitride (CON), or platinum nitride (PtN).

A first metal layer M1 may be provided in the third interlayer insulating layer 130. For example, the first metal layer M1 may include the first power line M1_R1, the second power line M1_R2, and first interconnection lines M1_I. The interconnection lines M1_R1, M1_R2, and M1_I of the first metal layer M1 may be extended in the second direction D2 to be parallel to each other.

For example, the first and second power lines M1_R1 and M1_R2 may be respectively provided on the third and fourth borders BD3 and BD4 of the single height cell SHC. The first power line M1_R1 may be extended along the third border BD3 and in the second direction D2. The second power line M1_R2 may be extended along the fourth border BD4 and in the second direction D2.

The first interconnection lines M1_I of the first metal layer M1 may be provided between the first and second power lines M1_R1 and M1_R2. The first interconnection lines M1_I of the first metal layer M1 may be arranged at a second pitch in the first direction D1. The second pitch may be smaller than the first pitch. A linewidth of each of the first interconnection lines M1_I may be smaller than a linewidth of each of the first and second power lines M1_R1 and M1_R2.

The first metal layer M1 may further include first vias VI1. The first vias VI1 may be provided below the interconnection lines M1_R1, M1_R2, and M1_I, respectively, of the first metal layer M1. The active contact AC and the interconnection line of the first metal layer M1 may be electrically connected to each other through the first via VI1. The gate contact GC and the interconnection line of the first metal layer M1 may be electrically connected to each other through the first via VI1.

The interconnection line of the first metal layer M1 and the first via VI1 thereunder may be formed by separate processes. For example, the interconnection line and the first via VI1 of the first metal layer M1 may be independently formed by respective single damascene processes. According to an embodiment, the semiconductor device may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may be extended in the first direction D1 to be parallel to each other.

The second metal layer M2 may further include second vias VI2, which are respectively provided below the second interconnection lines M2_I. The interconnection lines of the first and second metal layers M1 and M2 may be electrically connected to each other through the second via VI2. The interconnection line of the second metal layer M2 and the second via VI2 thereunder may be formed together by a dual damascene process.

The interconnection lines of the first metal layer M1 may include a conductive material that is the same as or different from those of the second metal layer M2. For example, the interconnection lines of the first and second metal layers M1 and M2 may be formed of or include at least one of metallic materials (e.g., aluminum, copper, tungsten, ruthenium, molybdenum, and cobalt). According to an embodiment, a plurality of metal layers (e.g., a third metal layer M3, a fourth metal layer M4, a fifth metal layer M5, and so forth) may be additionally stacked on the fourth interlayer insulating layer 140. Each of the stacked metal layers may include interconnection lines, which are used as routing paths between cells.

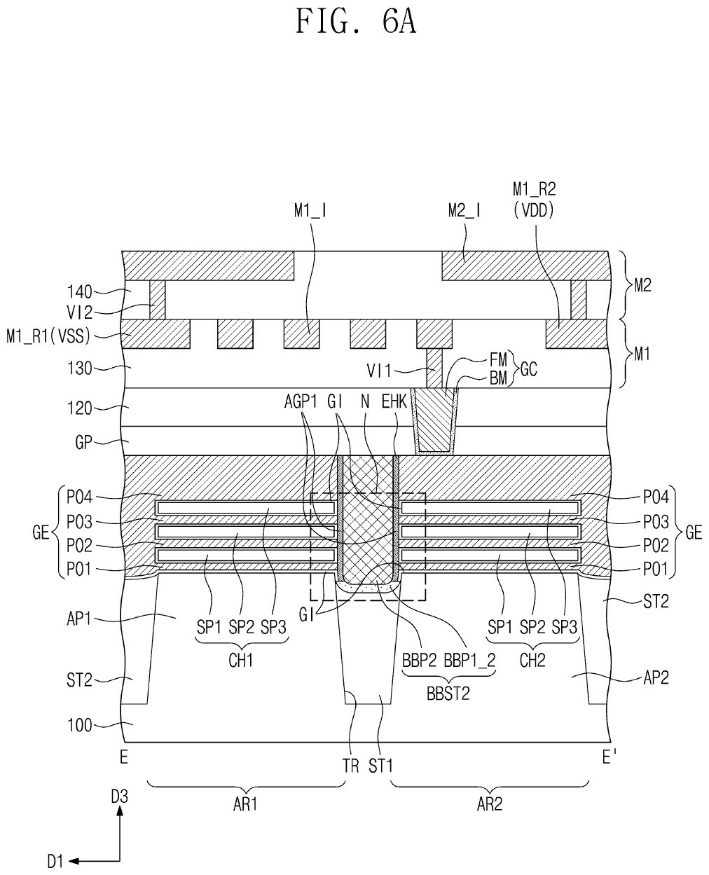

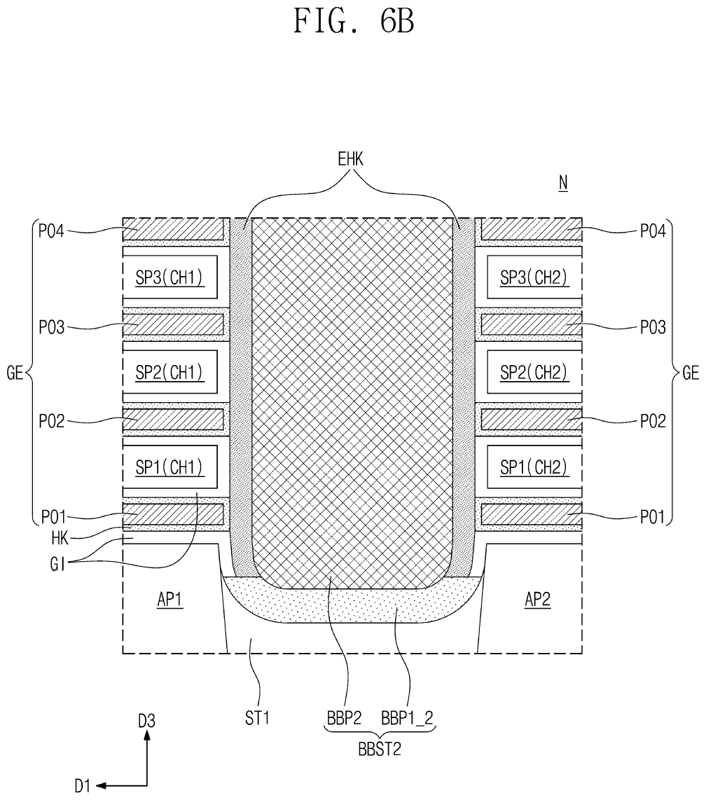

For concise description, an element previously described with reference to FIG. 4 and FIGS. 5A to 5F may be identified by the same reference number without repeating an overlapping description thereof. FIG. 6A is a sectional view illustrating another example of the structure of FIG. 5E, and FIG. 6B is an enlarged sectional view illustrating a portion ‘N’ of FIG. 6A.

Referring to FIG. 6A, a high-k dielectric pattern EHK may be provided on the second sub-backbone pattern BBP1_2 of the second backbone structure BBST2. According to an embodiment, a high-k dielectric pattern EHK may have a dielectric constant higher than a reference value. The high-k dielectric pattern EHK may be extended from a top surface of the second sub-backbone pattern BBP1_2 along the side surface of the second backbone pattern BBP2. The high-k dielectric pattern EHK may have a substantially constant thickness. The uppermost surface of the high-k dielectric pattern EHK may be substantially coplanar with the uppermost surface of the second backbone pattern BBP2 and the uppermost surface of the gate electrode GE.

Referring to FIG. 6B, the high-k dielectric pattern EHK may be interposed between the first to third semiconductor patterns SP1, SP2, and SP3 and the second backbone pattern BBP2. For example, the high-k dielectric pattern EHK may be interposed between the gate insulating layer GI, which is formed on each of the first to third semiconductor patterns SP1, SP2, and SP3 and the first and second active patterns AP1 and AP2, and the second backbone pattern BBP2. In other words, the high-k dielectric pattern EHK may be in direct contact with the gate insulating layer GI. The high-k dielectric pattern EHK may be in direct contact with the high-k dielectric layer HK between the gate insulating layer GI and the gate electrode GE.

The high-k dielectric pattern EHK and the high-k dielectric layer HK may be formed of or include at least one of high-k dielectric materials having dielectric constants higher than the dielectric constant of silicon oxide. In an embodiment, the high-k dielectric material may include, but is not limited to, at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The high-k dielectric pattern EHK and the high-k dielectric layer HK may include different high-k dielectric materials from each other. For example, the high-k dielectric layer HK may be formed of or include hafnium oxide or hafnium silicon oxide, and the high-k dielectric pattern EHK may be formed of or include lanthanum oxide or zirconium oxide. In an embodiment, the high-k dielectric pattern EHK and the high-k dielectric layer HK may be formed of or include the same high-k dielectric material.

According to an embodiment, by additionally forming the high-k dielectric pattern EHK between the semiconductor patterns SP1-SP3 and the backbone structure BBST2, it may be possible to improve a current density of the semiconductor patterns SP1-SP3.

Furthermore, by forming the high-k dielectric pattern EHK on the backbone structure BBST2, it may be possible to improve the gate controllability of the gate electrode GE near the semiconductor patterns SP1-SP3. For example, a transistor may be quickly driven by a bias applied to the gate electrode GE, and as such, it may be possible to improve the driving ability of the gate electrode GE.

In other words, by forming the high-k dielectric pattern EHK, it may be possible to improve the electrical characteristics of a forksheet semiconductor device.

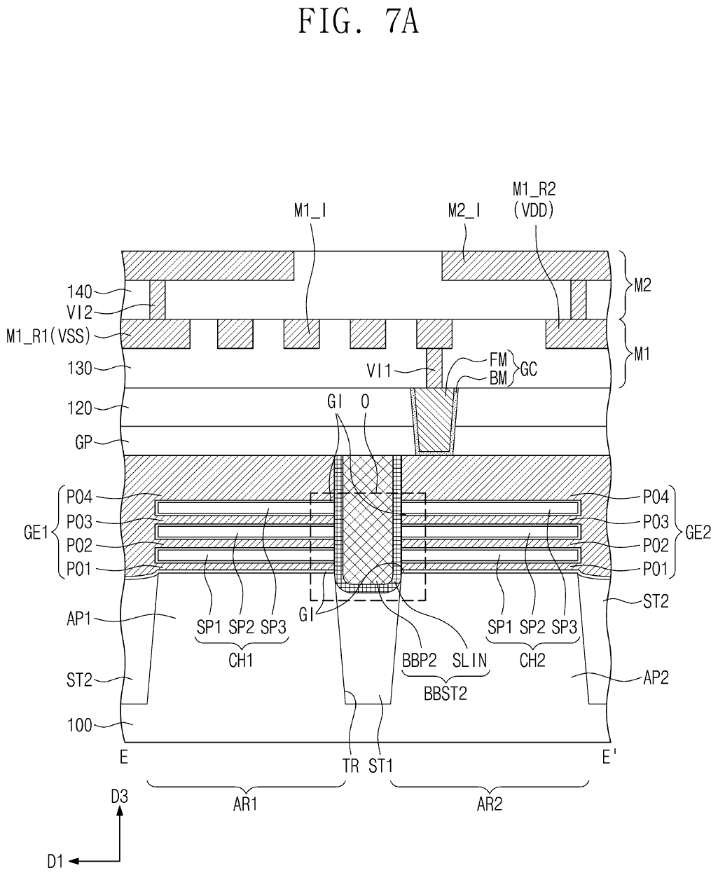

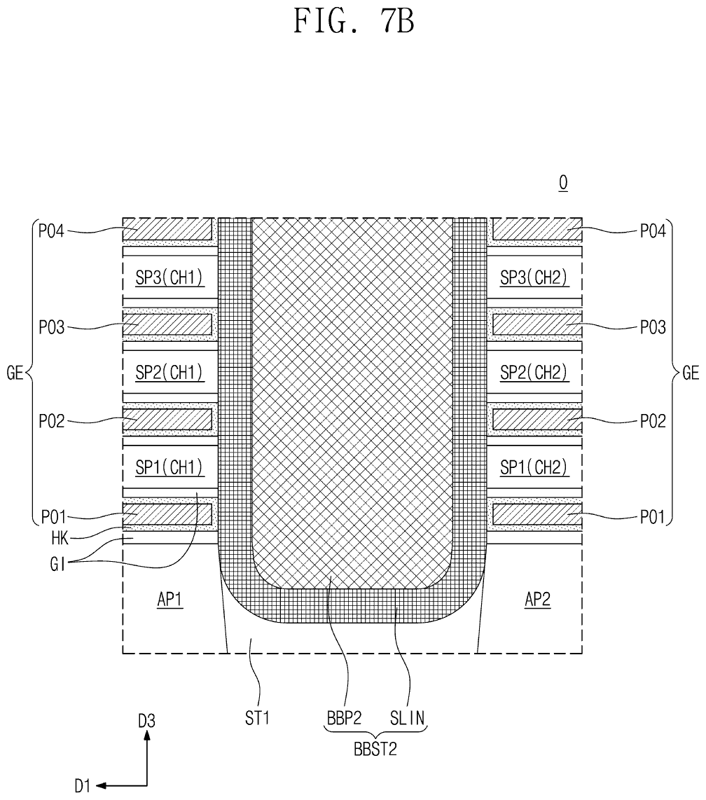

For concise description, an element previously described with reference to FIG. 4 and FIGS. 5A to 5F may be identified by the same reference number without repeating an overlapping description thereof. FIG. 7A is a sectional view illustrating still other example of the structure of FIG. 5E, and FIG. 7B is an enlarged sectional view illustrating a portion ‘O’ of FIG. 7A.

Referring to FIG. 7A, the first channel pattern CH1 may be provided on the first active pattern AP1, and the first channel pattern CH1 may include the first to third semiconductor patterns SP1, SP2, and SP3. The first source/drain pattern SD1 of FIG. 5D may be connected to the first channel pattern CH1. A first gate electrode GE1 may be provided on a top surface, a bottom surface, and a side surface of each of the first to third semiconductor patterns SP1, SP2, and SP3 of the first channel pattern CH1.

The second active pattern AP2 may be provided on the second channel pattern CH2, and the second channel pattern CH2 may include the first to third semiconductor patterns SP1, SP2, and SP3. The second source/drain pattern SD2 of FIG. 5D may be connected to the second channel pattern CH2. A second gate electrode GE2 may be provided on a top surface, a bottom surface, and a side surface of each of the first to third semiconductor patterns SP1, SP2, and SP3 of the second channel pattern CH2.

The second backbone structure BBST2 may be interposed between the first and second gate electrodes GE1 and GE2. For example, the second backbone structure BBST2 may be provided on the first device isolation layer ST1 and may be interposed between the first and second gate electrodes GE1 and GE2. The second backbone structure BBST2 may include a liner pattern SLIN provided on the first device isolation layer ST1, and a second backbone pattern BBP2 provided to fill a space defined by the liner pattern SLIN.

The liner pattern SLIN may be extended from a side surface of the first gate electrode GE1 to a side surface of the second gate electrode GE2 via a top surface of the first device isolation layer ST1. The uppermost surface of the liner pattern SLIN may be substantially coplanar with the uppermost surface of the second backbone pattern BBP2, the uppermost surface of the first gate electrode GE1, and the uppermost surface of the second gate electrode GE2. The liner pattern SLIN may have a constant thickness.

Referring to FIG. 7B, the gate insulating layer GI may be provided on each of the first to third semiconductor patterns SP1, SP2, and SP3 and the first and second active patterns AP1 and AP2. The high-k dielectric layer HK may be interposed between the gate insulating layer GI and the first gate electrode GE1 and between the gate insulating layer GI and the second gate electrode GE2.

The liner pattern SLIN may be in direct contact with the high-k dielectric layer HK and the gate insulating layer GI. The liner pattern SLIN may be in direct contact with the first to third semiconductor patterns SP1, SP2, and SP3. For example, side surfaces of the liner pattern SLIN may be in direct contact with an opposite side surface of each of the first to third semiconductor patterns SP1, SP2, and SP3. The opposite side surface may be opposite to the afore-described side surface of each of the first to third semiconductor patterns SP1, SP2, and SP3 in the first direction D1. That is, the first or second gate electrode GEL or GE2 may be provided on a first side surface of each of the first to third semiconductor patterns SP1, SP2, and SP3, and the liner pattern SLIN may be provided on a second side surface of each of the first to third semiconductor patterns SP1, SP2, and SP3, the second side surface being on an opposite side of the first side surface.

Referring back to FIGS. 5D, 7A, and 7B, the first and second active regions AR1 and AR2 may be NMOSFET regions, which are adjacent to each other. The first and second source/drain patterns SD1 and SD2 may be impurity regions of a first conductivity type (e.g., n-type). The first and second source/drain patterns SD1 and SD2 may be formed of or include the same semiconductor material (e.g., silicon Si) as the substrate 100. The first and second source/drain patterns SD1 and SD2 may further contain impurities that allow them to have an n-type conductivity. For example, the impurities may include, but is not limited to phosphorus, arsenic, or antimony.

In this example case in which the first and second active regions AR1 and AR2 are NMOSFET regions, the majority carrier of each of the first and second channel patterns CH1 and CH2 may be electrons. Since the electrons have a relatively fast mobility, the liner pattern SLIN may be formed of or include a material having a lower thermal expansion coefficient than silicon. For example, the liner pattern SLIN may be formed of or include at least one of SiO₂, BPSG, SiOC, or combinations thereof. A thermal expansion coefficient of the liner pattern SLIN may range from 0.5×10⁻⁶ (/° C.) to 3.0×10⁻⁶ (/° C.).

In another embodiment, the first and second active regions AR1 and AR2 may be PMOSFET regions, which are adjacent to each other. The first and second source/drain patterns SD1 and SD2 may be impurity regions of the second conductivity type (e.g., p-type). The first and second source/drain patterns SD1 and SD2 may include a semiconductor material (e.g., SiGe) whose lattice constant is greater than the semiconductor material (e.g., Si) of the substrate 100. The first and second source/drain patterns SD1 and SD2 may contain an impurity that allows them to have a p-type conductivity. For example, the impurities may include, but is not limited to, boron, gallium, or indium.

In this example case in which the first and second active regions AR1 and AR2 are PMOSFET regions, the majority carrier of each of the first and second channel patterns CH1 and CH2 may be holes. Since the holes have a relatively slow mobility, the liner pattern SLIN may be formed of or include a material having a thermal expansion coefficient higher than silicon. For example, the liner pattern SLIN may be formed of or include at least one of Si₃N₄, SiC, AlN, Al₂O₃, or combinations thereof. The liner pattern SLIN may have a thermal expansion coefficient ranging from 3.0×10⁻⁶ (/° C.) to 8.0×10⁻⁶ (/° C.).

In an embodiment, the liner pattern SLIN may be configured to exert different stresses on the channel patterns CH1 or CH2, depending on how the deposition process is performed. In an example case in which the first and second active regions AR1 and AR2 are NMOSFET regions, the liner pattern SLIN may be formed of or include a SiO₂ layer, which is deposited by performing a chemical vapor deposition (CVD) process. In an example case in which the first and second active regions AR1 and AR2 are PMOSFET regions, the liner pattern SLIN may be formed of or include Si₃N₄ or polysilicon.

In the semiconductor device according to an embodiment of the disclosure, since the liner pattern SLIN is formed between the semiconductor patterns SP1-SP3 and the second backbone pattern BBP2, it may be possible to adjust the stress, which is exerted on the semiconductor patterns SP1-SP3, depending on the NMOSFET or PMOSFET region.

For example, for the NMOSFET region where the majority carrier of the semiconductor patterns SP1-SP3 is the electron, the liner pattern SLIN may exert a tensile stress on the channel patterns CH1 and CH2 to increase the mobility of electron. For the PMOSFET region where the majority carrier of the semiconductor patterns SP1-SP3 is the hole, the liner pattern SLIN may exert a compressive stress on the channel patterns CH1 and CH2 to increase the mobility of hole. That is, by adjusting the stress using the liner pattern SLIN, it may be possible to increase the mobility of the carriers in the channel patterns CH1 and CH2.

In other words, by forming the liner pattern SLIN, it may be possible to improve the electrical characteristics of a forksheet semiconductor device.

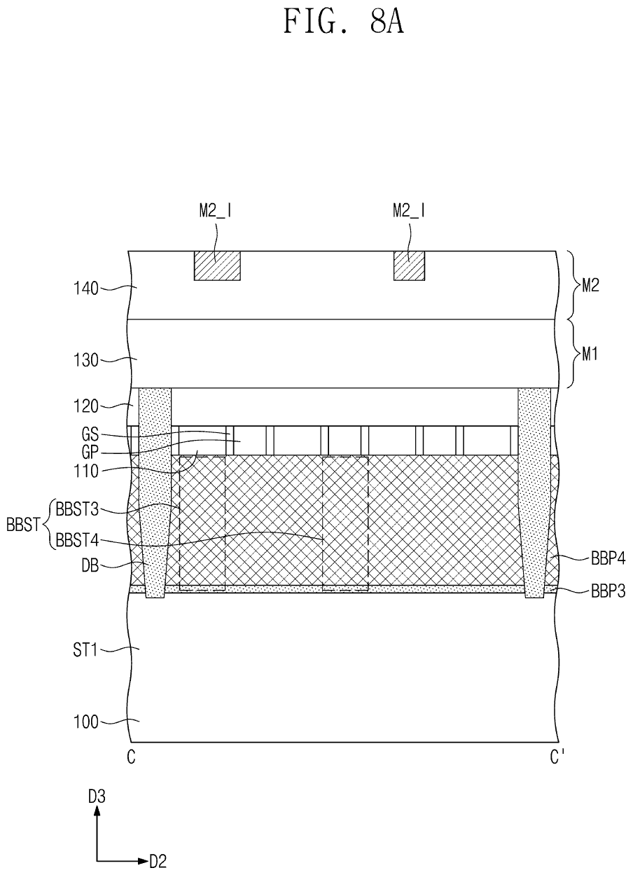

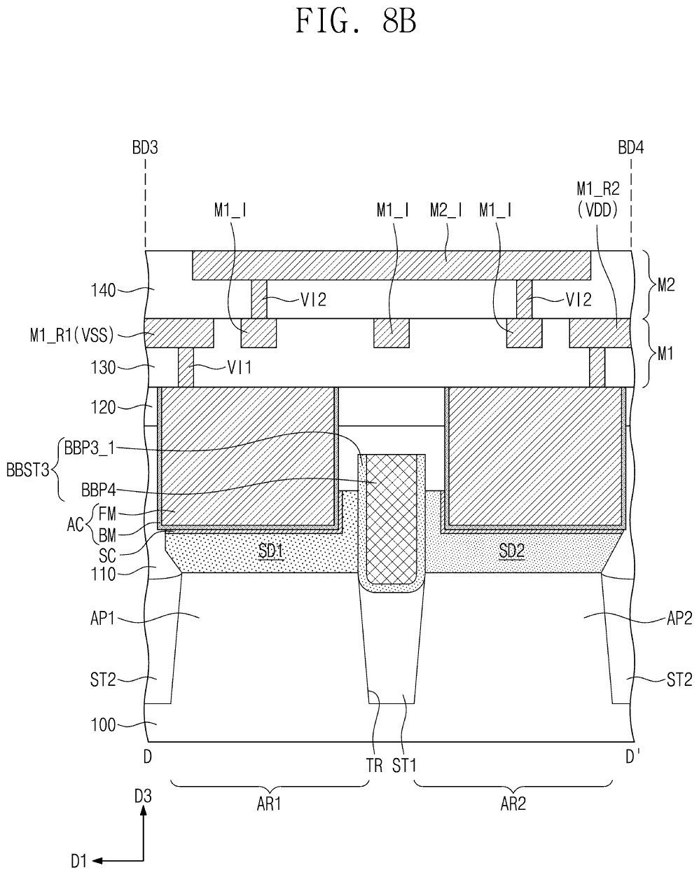

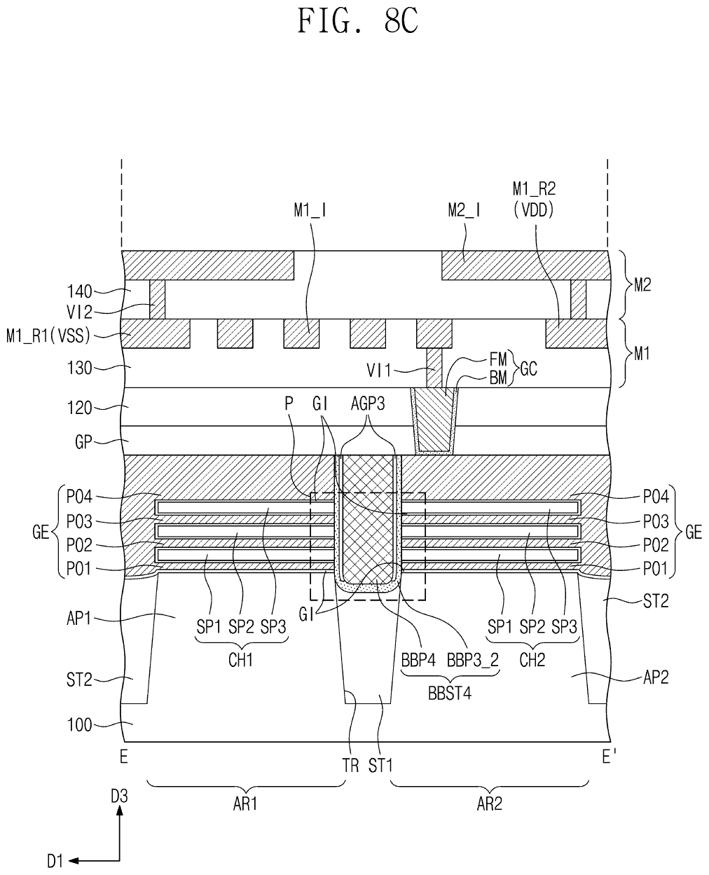

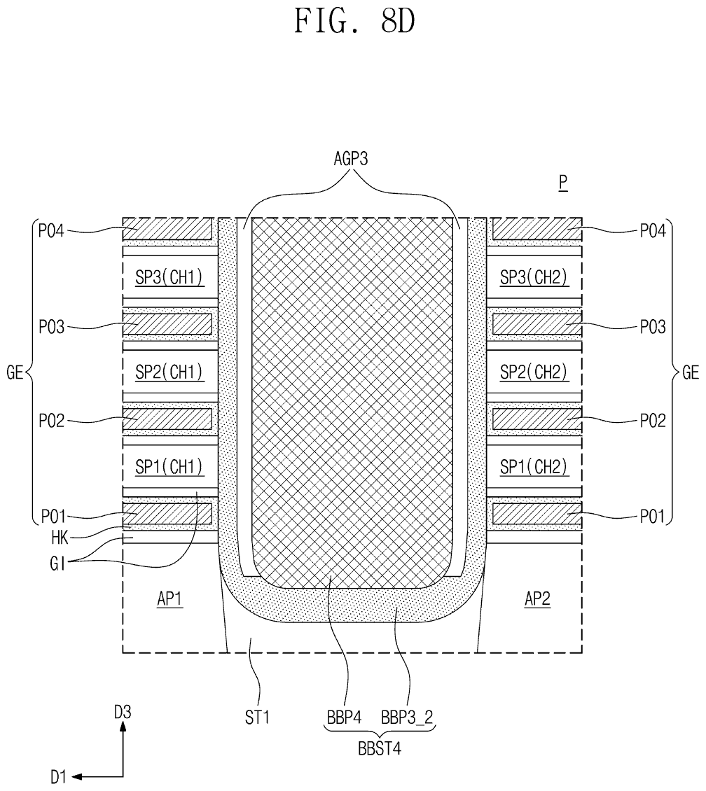

For concise description, an element previously described with reference to FIG. 4 and FIGS. 5A to 5F may be identified by the same reference number without repeating an overlapping description thereof. FIGS. 8A to 8C are sectional views illustrating other examples of the structures of FIGS. 5C to 5E, and FIG. 8D is an enlarged sectional view illustrating a portion ‘P’ of FIG. 8C.

Referring to FIGS. 8A to 8C, the backbone structure BBST may be provided on the first device isolation layer ST1. The backbone structure BBST may include a third backbone structure BBST3 and a fourth backbone structure BBST4. Each of the third and fourth backbone structures BBST3 and BBST4 may be defined as a portion of the backbone structure BBST. The third backbone structure BBST3 may be interposed between the first and second source/drain patterns SD1 and SD2. The fourth backbone structure BBST4 may be interposed between the gate electrodes GE.

Each of the third and fourth backbone structures BBST3 and BBST4 may include a third backbone pattern BBP3 and a fourth backbone pattern BBP4. The third backbone pattern BBP3 may be provided on the first device isolation layer ST1. The third backbone pattern BBP3 may have a constant thickness in the third direction D3. The third backbone pattern BBP3 may include a third sub-backbone pattern BBP3_1 and a fourth sub-backbone pattern BBP3_2. The fourth backbone pattern BBP4 may be provided on the third backbone pattern BBP3. The third backbone pattern BBP3 may be formed of or include the same material as the first backbone pattern BBP1, and the fourth backbone pattern BBP4 may be formed of or include the same material as the second backbone pattern BBP2.

The third and fourth backbone patterns BBP3 and BBP4 may include insulating materials having different etch rates from each other or have an etch selectivity with respect to each other. For example, the third backbone pattern BBP3 may be formed of or include silicon oxide, and the fourth backbone pattern BBP4 may be formed of or include silicon nitride.

The third backbone structure BBST3 may be provided on the first device isolation layer ST1 and may be interposed between the first and second source/drain patterns SD1 and SD2. The uppermost surface of the third backbone structure BBST3 may be located at a level that is higher than the uppermost surface of each of the first and second source/drain patterns SD1 and SD2 in the third direction D3 (e.g., see FIG. 8B).

For example, the third backbone structure BBST3 may include the third sub-backbone pattern BBP3_1 and the fourth backbone pattern BBP4 on the third sub-backbone pattern BBP3_1. The third sub-backbone pattern BBP3_1 may be in direct contact with the first and second source/drain patterns SD1 and SD2. In other words, the third sub-backbone pattern BBP3_1 may be extended to cover a side surface of the first source/drain pattern SD1, the top surface of the first device isolation layer ST1, and a side surface of the second source/drain pattern SD2. The third sub-backbone pattern BBP3_1 may have a substantially constant thickness. The fourth backbone pattern BBP4 may be provided to fill a space defined by the third sub-backbone pattern BBP3_1 or may be enclosed by the third sub-backbone pattern BBP3_1.

The fourth backbone structure BBST4 may be provided on the first device isolation layer ST1 and may be interposed between the gate electrodes GE. The uppermost surface of the fourth backbone structure BBST4 may be located at the same level as the uppermost surface of the gate electrodes GE in the third direction D3. In other words, the uppermost surface of the fourth backbone structure BBST4 may be substantially coplanar with the uppermost surface of the gate electrode GE.

The fourth backbone structure BBST4 may include the fourth sub-backbone pattern BBP3_2, the fourth backbone pattern BBP4 on the fourth sub-backbone pattern BBP3_2, and a third air gap pattern AGP3. The third air gap pattern AGP3 may be interposed between the fourth sub-backbone pattern BBP3_2 and the fourth backbone pattern BBP4. The fourth sub-backbone pattern BBP3_2 may be extended from a bottom surface of the fourth backbone pattern BBP4 to be spaced apart from the side surface of the fourth backbone pattern BBP4 with the third air gap pattern AGP3 interposed between the fourth sub-backbone pattern BBP3_2 and the fourth backbone pattern BBP4.

Referring to FIG. 8D, the gate insulating layer GI may be provided on each of the first to third semiconductor patterns SP1, SP2, and SP3 and the first and second active patterns AP1 and AP2. The high-k dielectric layer HK may be interposed between the gate insulating layer GI and the gate electrode GE.

The fourth sub-backbone pattern BBP3_2 may be in direct contact with the high-k dielectric layer HK and the gate insulating layer GI. The fourth sub-backbone pattern BBP3_2 may be in direct contact with the first to third semiconductor patterns SP1, SP2, and SP3. For example, a side surface of the fourth sub-backbone pattern BBP3_2 may be in direct contact with a side surface of each of the first to third semiconductor patterns SP1, SP2, and SP3.

Since the third air gap pattern AGP3 is interposed between the fourth sub-backbone pattern BBP3_2 and the fourth backbone pattern BBP4, the first to third semiconductor patterns SP1, SP2, and SP3 and the gate electrode GE may be spaced apart from each other. The lowermost surface of the third air gap pattern AGP3 may be located at a level which is lower than a top surface of each of the first and second active patterns AP1 and AP2 in the third direction D3. The lowermost surface of the third air gap pattern AGP3 may be located at a level which is higher than the lowermost surface of the fourth sub-backbone pattern BBP3_2 and the lowermost surface of the fourth backbone pattern BBP4 in the third direction D3. In other words, the lowermost surface of the third air gap pattern AGP3 may be located between the lowermost surface of the fourth backbone pattern BBP4 and the uppermost surface of each of the first and second active patterns AP1 and AP2.

Referring back to FIGS. 8C and 8D, the third air gap pattern AGP3 may be an empty space enclosed by the fourth sub-backbone pattern BBP3_2, the fourth backbone pattern BBP4, and the gate capping pattern GP. For example, the third air gap pattern AGP3 may be a void or a seam. The gate electrode GE may be provided on a top surface, a bottom surface, and a side surface of each of the first to third semiconductor patterns SP1, SP2, and SP3, and the third air gap pattern AGP3 may be provided on an opposite side surface of each of the first to third semiconductor patterns SP1, SP2, and SP3.

In the semiconductor device according to an embodiment of the disclosure, since the air layer (e.g., the air gap pattern AGP3) is formed in the backbone structure BBST4, it may be possible to reduce an undesired increase of a capacitance which occur when charges passing through the backbone structure BBST4 are trapped. That is, it may be possible to reduce a parasitic capacitance, which is caused by the backbone structure BBST4. Thus, it may be possible to improve performance of a cell including a transistor.

In addition, by forming the backbone structure BBST, it may be possible to reduce a distance between transistors in different regions and thereby to reduce an occupying area of unit cell within a given substrate area. In other words, it may be possible to increase the number of the unit cells that can be formed on the substrate. Accordingly, the integration density of the semiconductor device may be improved.

As a result, since the air layer is formed in the backbone structure BBST4, it may be possible to improve the electrical characteristics of the semiconductor device and increase the integration density of the semiconductor device.

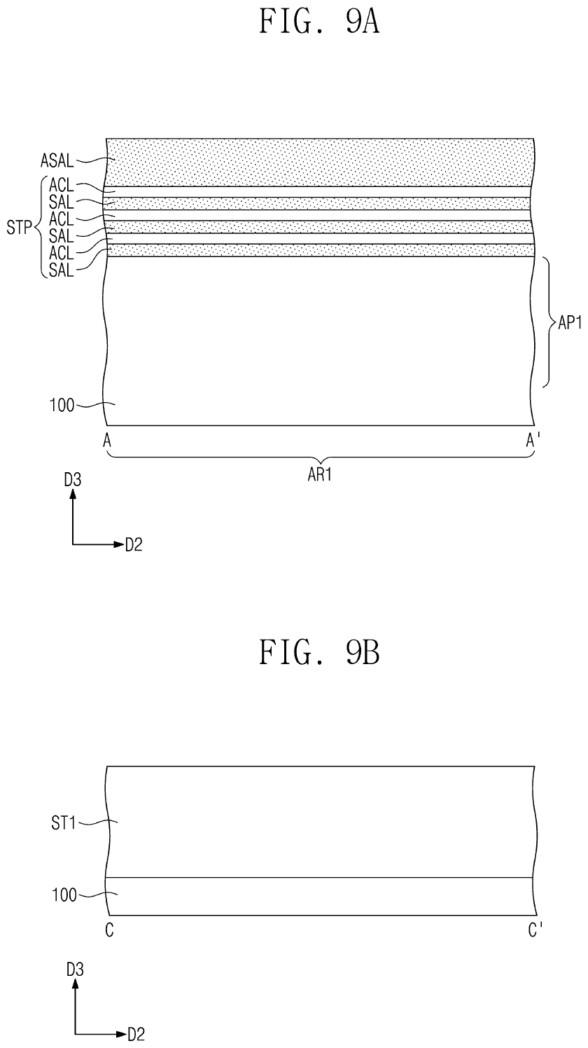

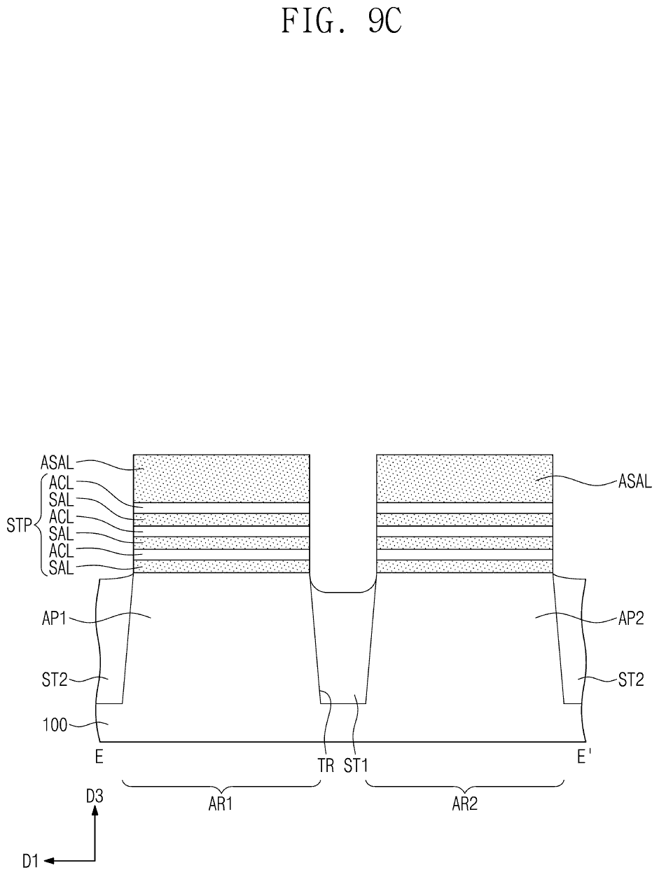

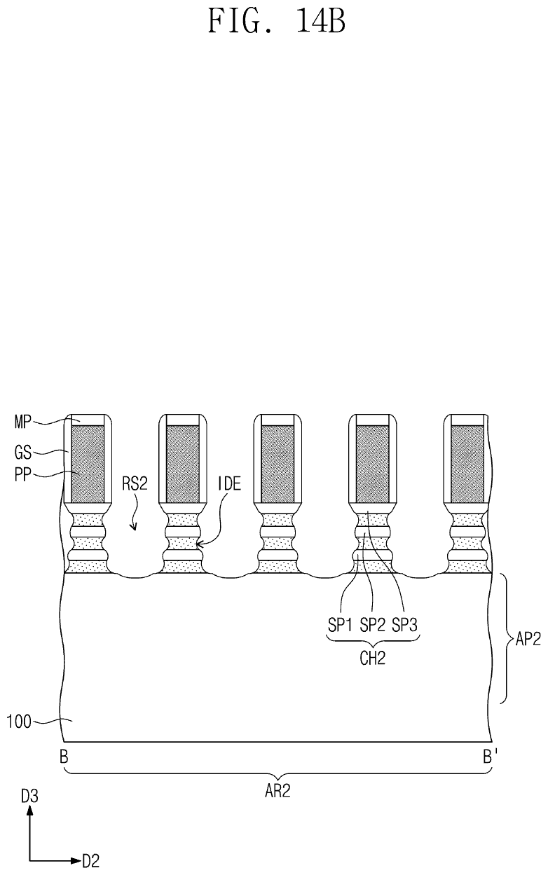

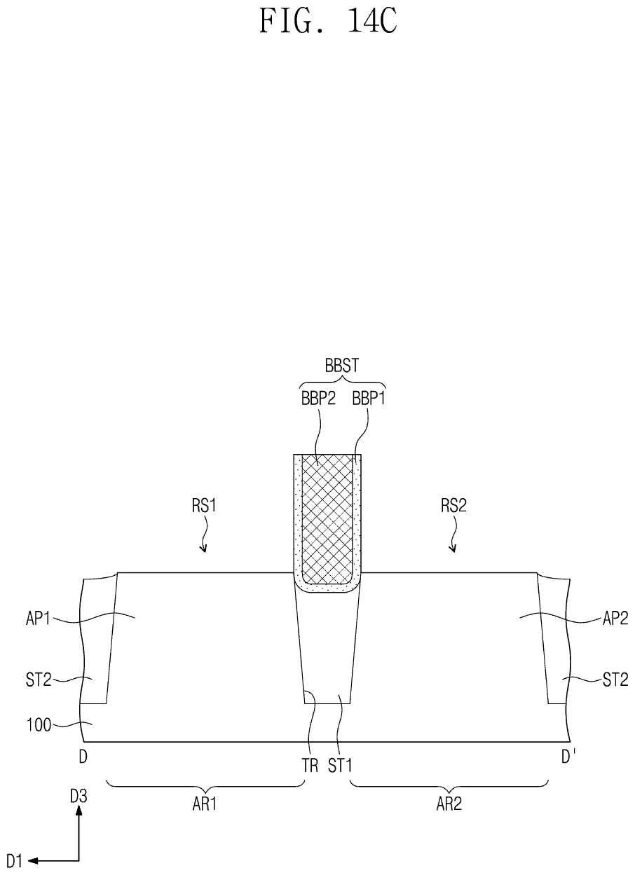

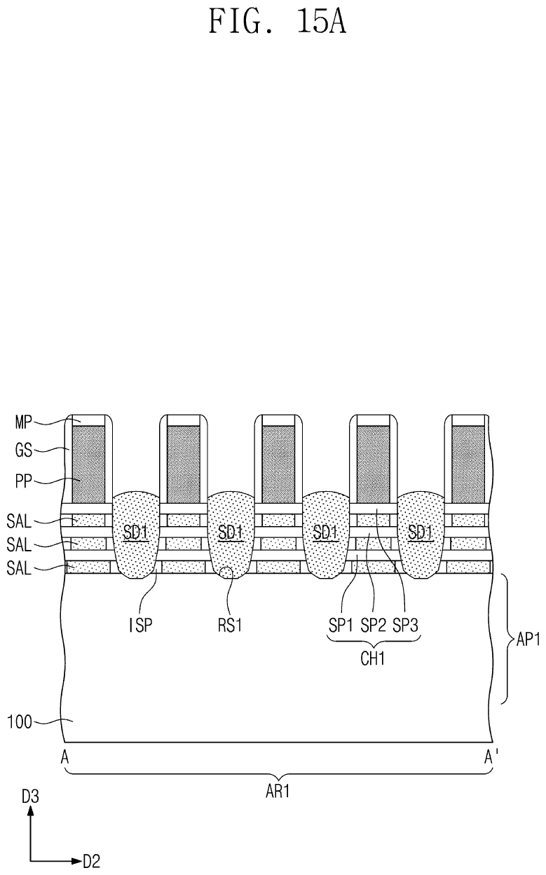

FIGS. 9A to 17E are sectional views illustrating a method of fabricating a semiconductor device according to an embodiment of the disclosure. For example, FIGS. 9A, 10A, 11A, 12A, 13A, 14A, 15A, 16A, and 17A are sectional views corresponding to a line A-A′ of FIG. 4. FIGS. 14B, 15B, 16B, and 17B are sectional views corresponding to a line B-B′ of FIG. 4. FIGS. 9B, 10B, 11B, 12B, 13B, 16C, and 17C are sectional views corresponding to a line C-C′ of FIG. 4. FIGS. 14C, 15C, 16D, and 17D are sectional views corresponding to a line D-D′ of FIG. 4. FIGS. 9C, 10C, 11C, 12C, 13C, 16E, and 17E are sectional views corresponding to a line E-E′ of FIG. 4.

Referring to FIGS. 9A to 9C, the substrate 100 including the first and second active regions AR1 and AR2 may be provided. The substrate 100 may be a semiconductor substrate that is formed of or includes silicon, germanium, silicon germanium, a compound semiconductor material, or the like. In an embodiment, the substrate 100 may be a silicon wafer. Active layers ACL and sacrificial layers SAL may be alternately stacked on the substrate 100. The active and sacrificial layers ACL and SAL may be formed of or include at least one of silicon (Si), germanium (Ge), or silicon-germanium (SiGe), and here, the active and sacrificial layers ACL and SAL may be formed of different materials from each other.

The sacrificial layer SAL may be formed of at least one of materials having an etch selectivity with respect to the active layer ACL. For example, the active layers ACL may be formed of or include silicon (Si), and the sacrificial layers SAL may be formed of or include silicon germanium (SiGe). A germanium concentration of each of the sacrificial layers SAL may range from 10 at % to 30 at %.

An additional sacrificial layer ASAL may be formed on the uppermost one of the active layers ACL. The additional sacrificial layer ASAL may be a preliminary sacrificial layer, which is used to remove a height difference, in the third direction D3, between the backbone structure BBST and the gate electrode GE which will be formed later. In the third direction D3, a thickness of the additional sacrificial layer ASAL may be larger than a thickness of each of the sacrificial and active layers SAL and ACL which are alternately stacked. For example, the thickness of the additional sacrificial layer ASAL may be 2.5 to 4.5 times a thickness of each of the sacrificial and active layers SAL and ACL. The additional sacrificial layers ASAL may be formed of or include silicon-germanium (SiGe).

Mask patterns may be formed on the first and second active regions AR1 and AR2 of the substrate 100, respectively. The mask pattern may be a line- or bar-shaped pattern that is extended in the second direction D2.

A patterning process using the mask patterns as an etch mask may be performed to form the trench TR defining the first and second active patterns AP1 and AP2. The first active pattern AP1 may be formed on the first active region AR1. The second active pattern AP2 may be formed on the second active region AR2.

Referring to FIG. 9C, a stacking pattern STP may be formed on each of the first and second active patterns AP1 and AP2. The stacking pattern STP may include the active layers ACL and the sacrificial layers SAL which are alternately stacked. The stacking pattern STP may be formed along with the first and second active patterns AP1 and AP2, during the patterning process. The additional sacrificial layer ASAL on the stacking pattern STP may be formed along with the first and second active patterns AP1 and AP2, during the patterning process.

The first and second device isolation layers ST1 and ST2 may be formed to fill the trench TR. For example, an insulating layer may be formed on the substrate 100 to cover the first and second active patterns AP1 and AP2, the stacking patterns STP, and the additional sacrificial layers ASAL. The first and second device isolation layers ST1 and ST2 may be formed by recessing the insulating layer to expose the additional sacrificial layers ASAL.

Referring to FIGS. 9B and 9C, the first device isolation layer ST1 may be formed to fill the trench TR between the first and second active patterns AP1 and AP2. The second device isolation layer ST2 may be formed to fill the trench on the third and fourth borders BD3 and BD4 of FIG. 4. The top surface of the first device isolation layer ST1 may be located at a level, which is lower than the top surface of the second device isolation layer ST2 in the third direction D3.

The first and second device isolation layers ST1 and ST2 may be formed of or include an insulating material (e.g., silicon oxide). The stacking patterns STP and the additional sacrificial layers ASAL may be provided on the first and second device isolation layers ST1 and ST2. That is, the stacking patterns STP and the additional sacrificial layers ASAL may vertically protrude above the first and second device isolation layers ST1 and ST2. For example, the stacking patterns STP and the additional sacrificial layers ASAL may be exposed to the outside.

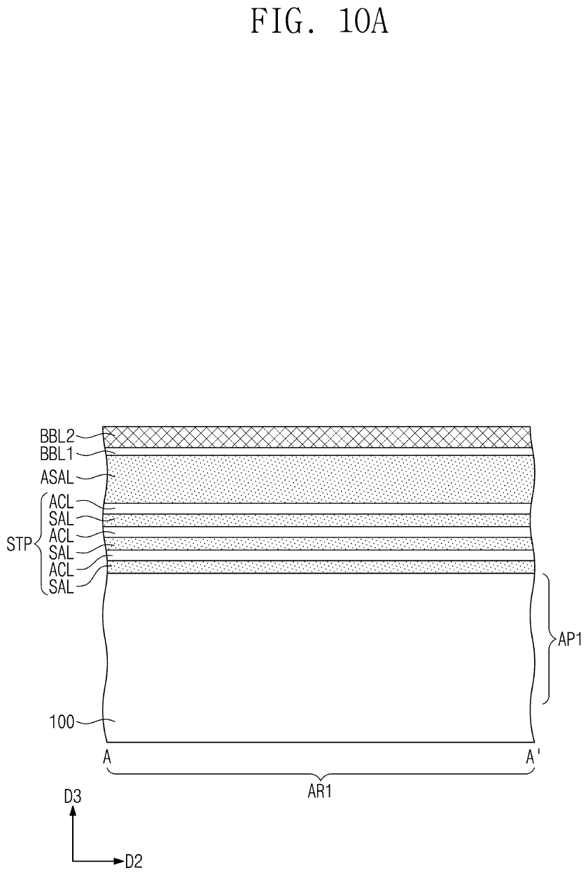

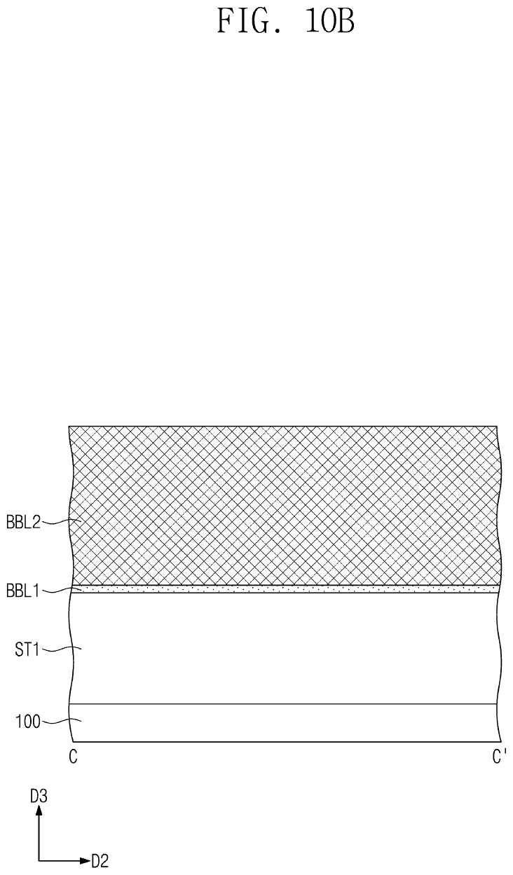

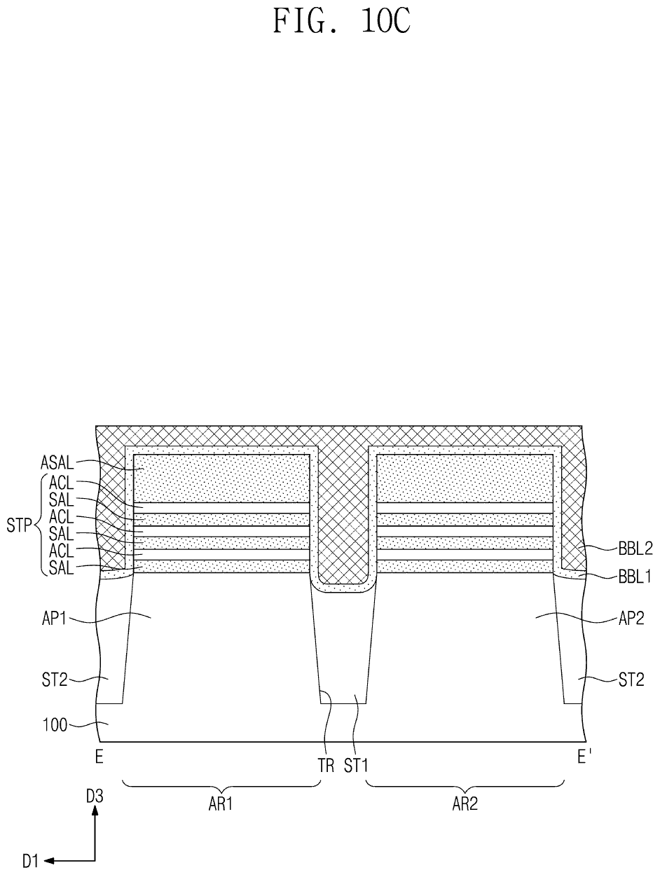

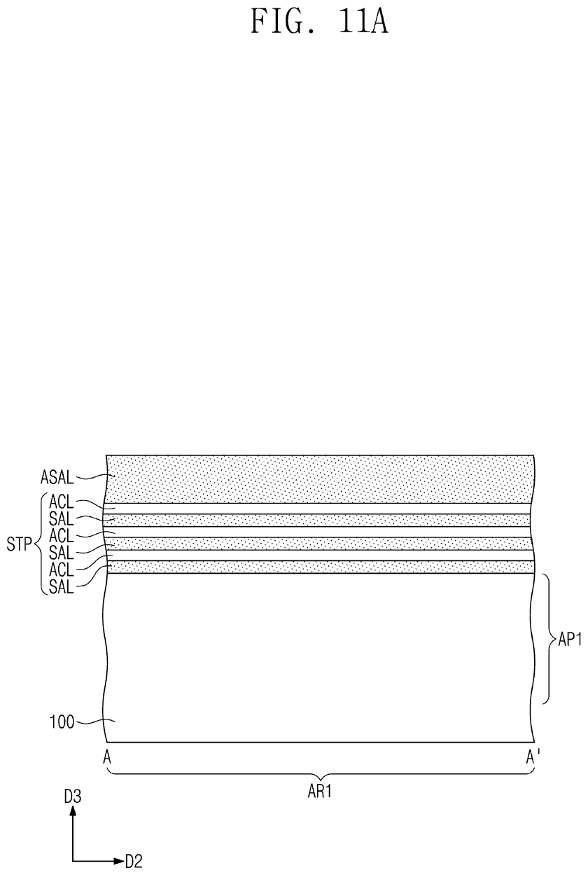

Referring to FIGS. 10A to 10C, a first backbone layer BBL1 may be formed on the first and second device isolation layers ST1 and ST2, the stacking patterns STP, and the additional sacrificial layers ASAL. The first backbone layer BBL1 may be provided on top surfaces of the first and second device isolation layers ST1 and ST2, side surfaces of the stacking patterns STP, and side and top surfaces of the additional sacrificial layers ASAL. For example, the first backbone layer BBL1 may cover top surfaces of the first and second device isolation layers ST1 and ST2, side surfaces of the stacking patterns STP, and side and top surfaces of the additional sacrificial layers ASAL. The first backbone layer BBL1 may be formed to have a constant thickness. The first backbone layer BBL1 may be formed by performing a chemical vapor deposition (CVD) process, a physical vapor deposition (PVD) process, or an atomic layer deposition (ALD) process.

A second backbone layer BBL2 may be formed on the first backbone layer BBL1. The second backbone layer BBL2 may fill a space between the stacking patterns STP and the additional sacrificial layers ASAL. That is, the second backbone layer BBL2 may be formed to fill a space defined by the first backbone layer BBL1, which is formed on the side surfaces of the stacking patterns STP and the side surfaces of the additional sacrificial layers ASAL. The second backbone layer BBL2 may be formed by performing a chemical vapor deposition (CVD) process or a physical vapor deposition (PVD) process.

The first and second backbone layers BBL1 and BBL2 may include insulating materials having different etch rates from each other or have an etch selectivity with respect to each other. The first backbone layer BBL1 may be formed of or include silicon oxide, and the second backbone layer BBL2 may be formed of or include silicon nitride or silicon oxynitride. In an embodiment, the second backbone layer BBL2 may be formed of or include silicon nitride, and in this case, it may be possible to secure a process margin in a high-selectivity etching process to be described below.

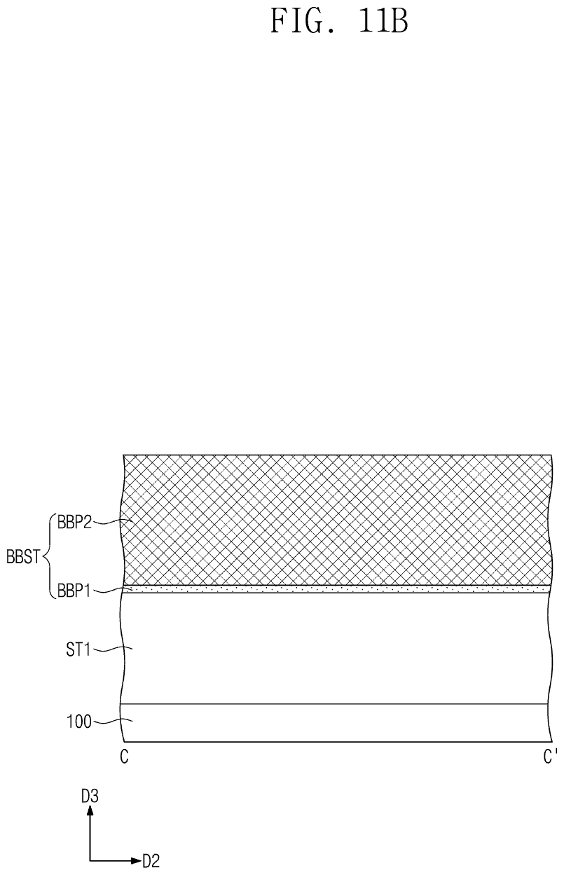

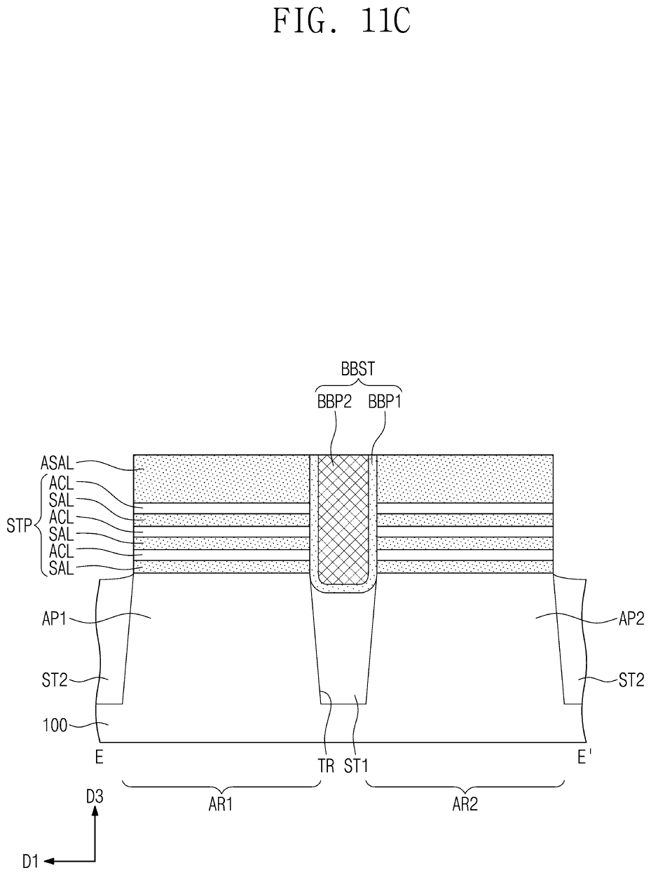

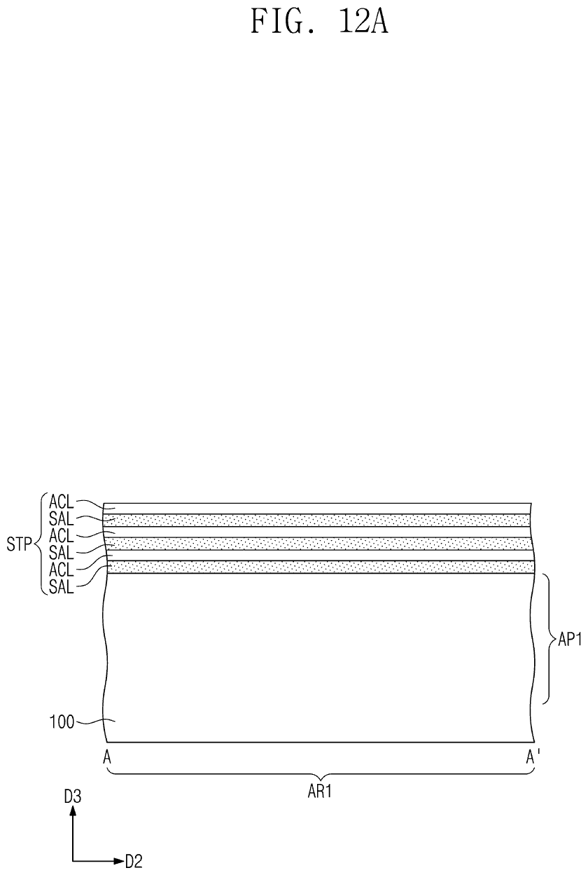

Referring to FIGS. 11A to 11C, the first and second backbone layers BBL1 and BBL2 may be planarized to expose a top surface of the additional sacrificial layers ASAL. The planarization of the first and second backbone layers BBL1 and BBL2 may be performed using a chemical mechanical polishing (CMP) process. In the CMP process, slurry, which has a higher etch rate to silicon oxide or silicon nitride than to silicon-germanium, may be used. Both the first and second backbone layers BBL1 and BBL2 on the additional sacrificial layers ASAL may be removed during the planarization process. As a result, the backbone structure BBST may be formed between the stacking patterns STP.

For example, the backbone structure BBST may be formed on the first device isolation layer ST1 and may be formed between the stacking patterns STP. The backbone structure BBST may include the first backbone pattern BBP1 on the first device isolation layer ST1 and the second backbone pattern BBP2 on the first backbone pattern BBP1. The first backbone pattern BBP1 may extend over a side surface of the additional sacrificial layer ASAL, a side surface of the stacking pattern STP, the top surface of the first device isolation layer ST1, a side surface of another stacking pattern STP, and a side surface of another additional sacrificial layer ASAL. For example the first backbone pattern BBP1 may be extended to cover a side surface of the additional sacrificial layer ASAL, a side surface of the stacking pattern STP, the top surface of the first device isolation layer ST1, a side surface of another stacking pattern STP, and a side surface of another additional sacrificial layer ASAL. A top surface of the first backbone pattern BBP1 and a top surface of the second backbone pattern BBP2 may be substantially coplanar with a top surface of each of the additional sacrificial layers ASAL.

A mask pattern may be formed on the additional sacrificial layers ASAL and the backbone structure BBST. The mask pattern may be a line- or bar-shaped pattern extended in the first direction D1.

An etching process using the mask pattern as an etch mask may be performed to remove the first and second backbone layers BBL1 and BBL2, which are left on the second device isolation layer ST2 after the planarization process. The etching process may be an anisotropic dry etching process. Since the first backbone layer BBL1 and the second device isolation layer ST2 include silicon oxide, an upper portion of the second device isolation layer ST2 may be slightly removed, during the etching process. Thus, the top surface of the second device isolation layer ST2 may be located at a level, which is higher than or equal to the top surface of the first device isolation layer ST1 in the third direction D3.

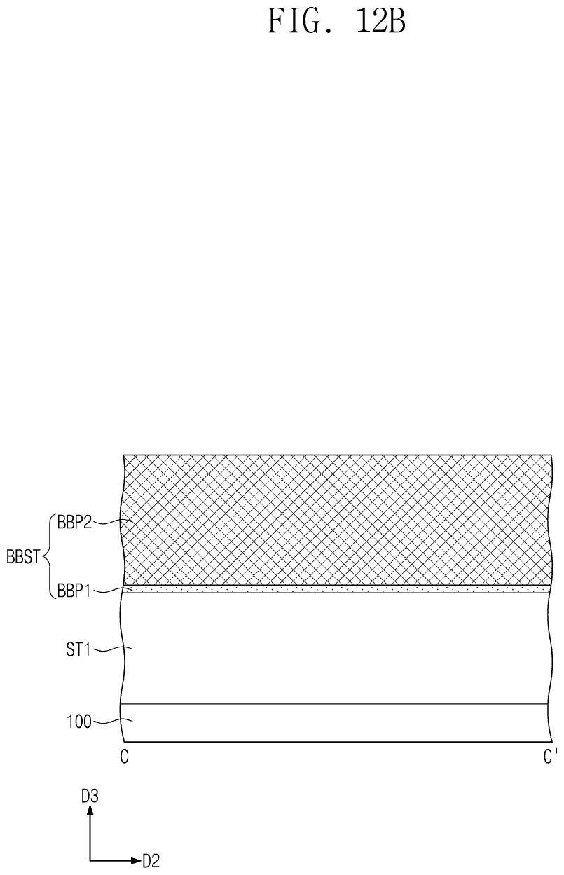

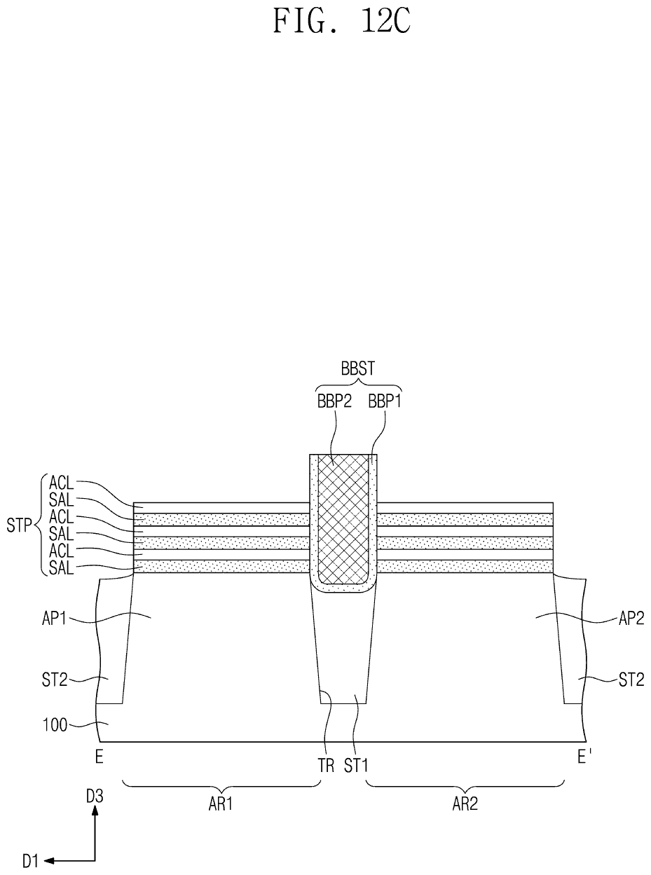

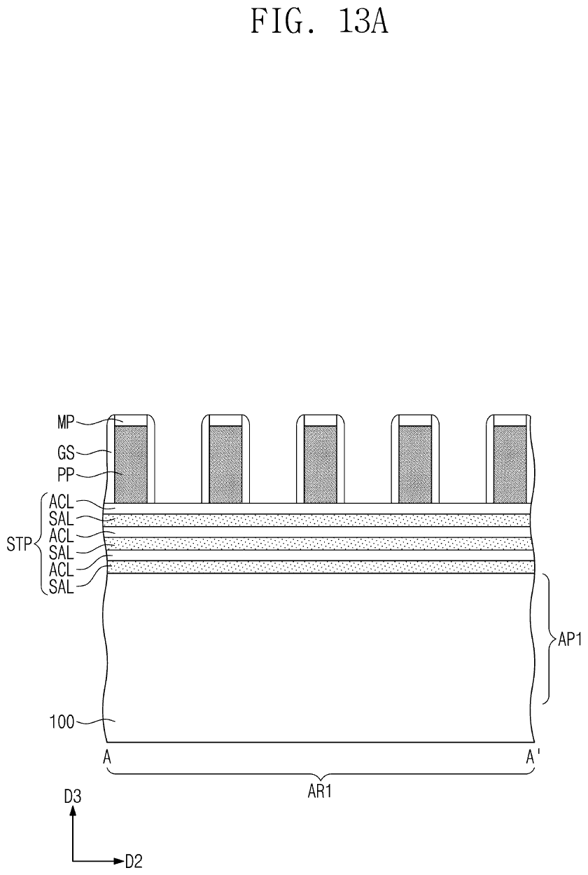

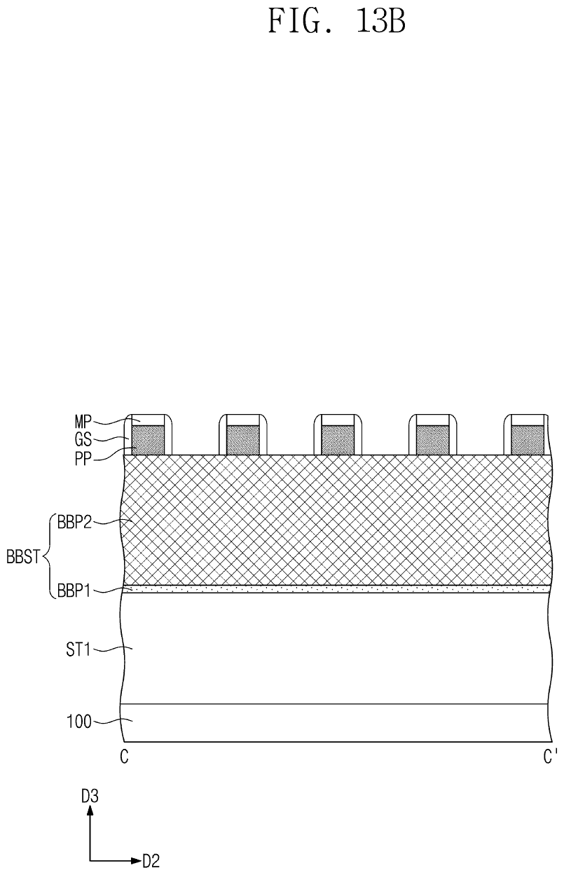

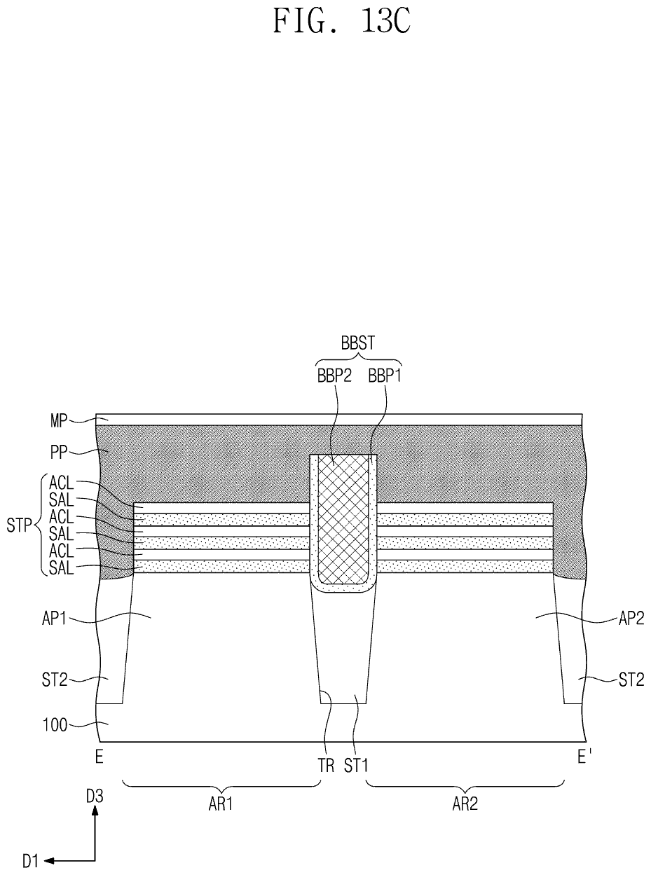

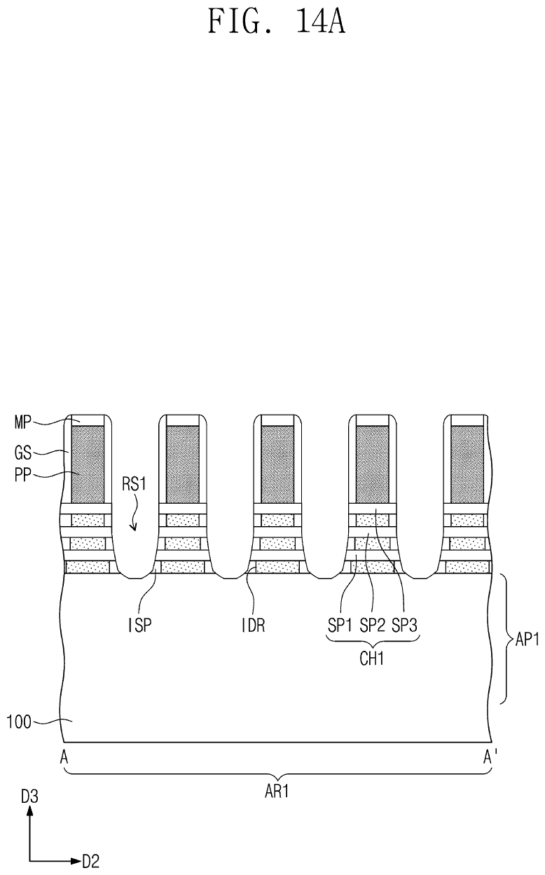

Referring to FIGS. 12A to 12C, the additional sacrificial layers ASAL may be selectively removed such that only the stacking pattern STP is left on each of the first and second active patterns AP1 and AP2 (e.g., see FIG. 12C). For example, a selective etching process may be performed to leave the stacking patterns STP and the backbone structure BBST and remove only the additional sacrificial layers ASAL. That is, the selective etching process may be performed to expose the stacking patterns STP and the backbone structure BBST. An etch recipe for the etching process may be chosen to etch a layer (e.g., a silicon germanium layer), which has a relatively high germanium concentration, at a high etch rate. For example, the etching process may be chosen to have a high etch rate to a silicon germanium layer whose germanium concentration is higher than 10 at %.

According to an embodiment, since only the additional sacrificial layers ASAL are selectively removed, a top surface of the backbone structure BBST may be located at a level, which is higher than a top surface of each of the stacking patterns STP in the third direction D3. A side surface of the first backbone pattern BBP1 may be partially exposed, during the etching process.

Referring to FIGS. 13A to 13C, sacrificial patterns PP may be formed on the substrate 100. For example, the sacrificial patterns PP may be formed across the stacking patterns STP and the backbone structure BBST. Each of the sacrificial patterns PP may be a line-shaped pattern or a bar-shaped pattern that is extended in the first direction D1. The sacrificial patterns PP may be arranged at a first pitch in the second direction D2.

For example, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may include, but is not limited to, polysilicon.

A pair of the gate spacers GS may be formed on opposite side surfaces of each of the sacrificial patterns PP. For example, a first gate spacer GS may be formed on a first side surface of a first sacrificial pattern PP and a second gate spacer GS may be formed on a second side surface of the first sacrificial pattern PP. The formation of the gate spacers GS may include conformally forming a gate spacer layer on the substrate 100 and anisotropically etching the gate spacer layer. In an embodiment, the gate spacer GS may be a multi-layered structure including at least two layers.

Referring to FIGS. 14A to 14C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the second device isolation layer ST2 may be further recessed at both sides of each of the first and second active patterns AP1 and AP2.

For example, the first recesses RS1 may be formed by etching the stacking pattern STP on the first active pattern AP1 using the hard mask patterns MP and the gate spacers GS as an etch mask. The first recess RS1 may be formed between a pair of the sacrificial patterns PP.

The first to third semiconductor patterns SP1, SP2, and SP3, which are sequentially stacked between adjacent ones of the first recesses RS1, may be respectively formed from the active layers ACL. The first to third semiconductor patterns SP1, SP2, and SP3 between adjacent ones of the first recesses RS1 may constitute the first channel pattern CH1.

Referring to FIG. 14A, the first recess RS1 may be formed between adjacent ones of the sacrificial patterns PP. A width of the first recess RS1 in the second direction D2 may decrease as a distance to the substrate 100 decreases. For example, a first width of the first recess RS1 in the second direction D2 at a first location from the substrate 100 is smaller than a second width of the first recess RS1 in the second direction D2 at a second location farther away from the substrate 100 than the first location.

The sacrificial layers SAL may be exposed by the first recess RS1. A selective etching process may be performed on the exposed sacrificial layers SAL. The etching process may include a wet etching process of selectively removing only silicon-germanium. As a result of the etching process, each of the sacrificial layers SAL may be indented to form an indent region IDR. Due to the presence of the indent region IDR, the sacrificial layer SAL may have a concave side surface. An insulating layer may be formed in the first recess RS1 to fill the indent regions IDR. The first to third semiconductor patterns SP1, SP2, and SP3 and the sacrificial layers SAL, which are exposed by the first recess RS1, may be used as a seed layer for the insulating layer.

The inner spacer ISP may be formed to fill the indent region IDR. For example, the formation of the inner spacer ISP may include performing a wet etching process on the insulating layer to expose side surfaces of the first to third semiconductor patterns SP1, SP2, and SP3. After the etching process, a portion of the insulating layer may be locally left in the indent region IDR to form the inner spacer ISP.

Referring to FIG. 14B, the second recesses RS2 in the stacking pattern STP on the second active pattern AP2 may be formed by a method that is similar to that for the first recesses RS1. A selective etching process may be performed on the sacrificial layers SAL, which are exposed by the second recess RS2, to form indent regions IDE on the second active pattern AP2. Due to the indent regions IDE, the second recess RS2 may have a wavy inner side surface. The inner spacers ISP may not be formed in the indent regions IDE on the second active pattern AP2. The first to third semiconductor patterns SP1, SP2, and SP3 between adjacent ones of the second recesses RS2 may constitute the second channel pattern CH2.

Referring to FIG. 14C, due to the first and second recesses RS1 and RS2 formed by recessing the stacking patterns STP, most of the backbone structure BBST may be exposed. For example, most of the side surface of the first backbone pattern BBP1 may be exposed. The backbone structure BBST may be a vertically protruding structure, which is placed between the first and second active patterns AP1 and AP2 and on the first device isolation layer ST1.

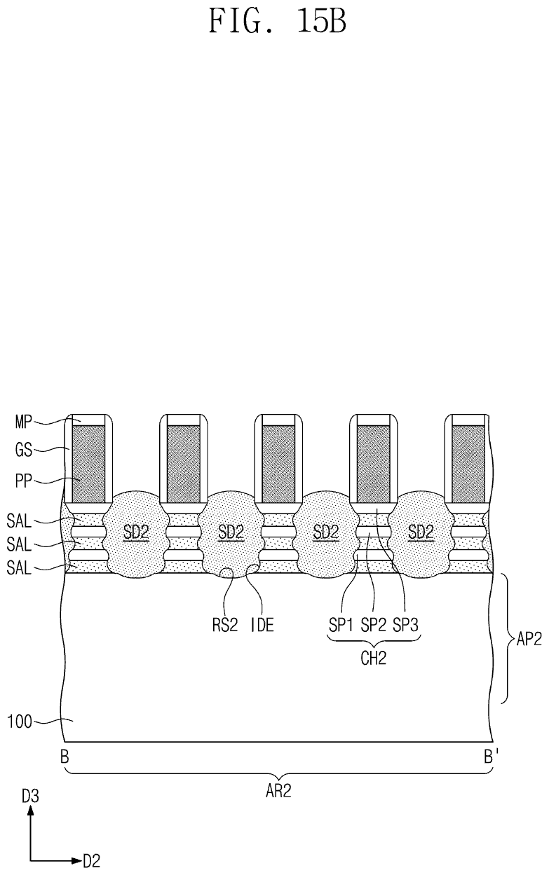

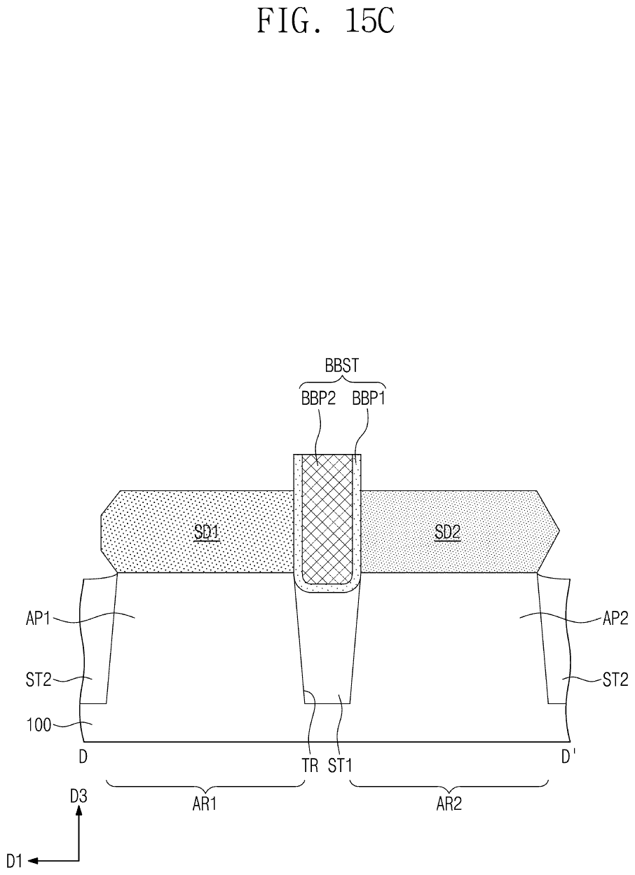

Referring to FIGS. 15A to 15C, the first source/drain patterns SD1 may be formed in the first recesses RS1, respectively. For example, a SEG process, in which an inner surface of the first recess RS1 is used as a seed layer, may be performed to form an epitaxial layer filling the first recess RS1. The epitaxial layer may be grown using the first to third semiconductor patterns SP1, SP2, and SP3 and the substrate 100, which are exposed by the first recess RS1, as the seed layer. In an embodiment, the SEG process may include a chemical vapor deposition (CVD) process or a molecular beam epitaxy (MBE) process.

In an embodiment, the first source/drain pattern SD1 may be formed of or include the same semiconductor element (e.g., silicon Si) as the substrate 100. During the formation of the first source/drain pattern SD1, the first source/drain pattern SD1 may be doped with n-type impurities (e.g., phosphorus, arsenic, or antimony). For example, while the first source/drain pattern SD1 is being formed, the first source/drain pattern SD1 may be doped in situ with the impurities. Alternatively, the impurities may be injected into the first source/drain pattern SD1, after the formation of the first source/drain pattern SD1.

The second source/drain patterns SD2 may be formed in the second recesses RS2, respectively. For example, the second source/drain pattern SD2 may be formed by a SEG process using an inner surface of the second recess RS2 as a seed layer.

In an embodiment, the second source/drain pattern SD2 may be formed of or include a semiconductor material (e.g., silicon-germanium SiGe) having a lattice constant that is greater than the lattice constant a semiconductor material of the substrate 100. During the formation of the second source/drain pattern SD2, the second source/drain pattern SD2 may be doped with p-type impurities (e.g., boron, gallium, or indium). For example, while the second source/drain pattern SD2 is being formed, the second source/drain pattern SD2 may be doped in-situ with the p-type impurities. Alternatively, the impurities may be injected into the second source/drain pattern SD2, after the formation of the second source/drain pattern SD2.

In an embodiment, the kind of impurities in the first and second source/drain patterns SD1 and SD2 may vary depending on whether each of the first and second active regions AR1 and AR2 is an NMOSFET or PMOSFET region. In an example case in which the first and second active regions AR1 and AR2 are the NMOSFET regions, the first and second source/drain patterns SD1 and SD2 may be doped in-situ with n-type impurities (e.g., phosphorus, arsenic, or antimony)). In an example case in which the first and second active regions AR1 and AR2 are the PMOSFET regions, the first and second source/drain patterns SD1 and SD2 may be doped in-situ with p-type impurities (e.g., boron, gallium, or indium).

Referring to FIG. 15C, a side surface of each of the first and second source/drain patterns SD1 and SD2 may be in direct contact with the backbone structure BBST. That is, the first backbone pattern BBP1 of the backbone structure BBST may be in direct contact with side surfaces of the first and second source/drain patterns SD1 and SD2. A top surface of each of the first and second source/drain patterns SD1 and SD2 may be located at a level, which is lower than the top surface of the backbone structure BBST in the third direction D3.

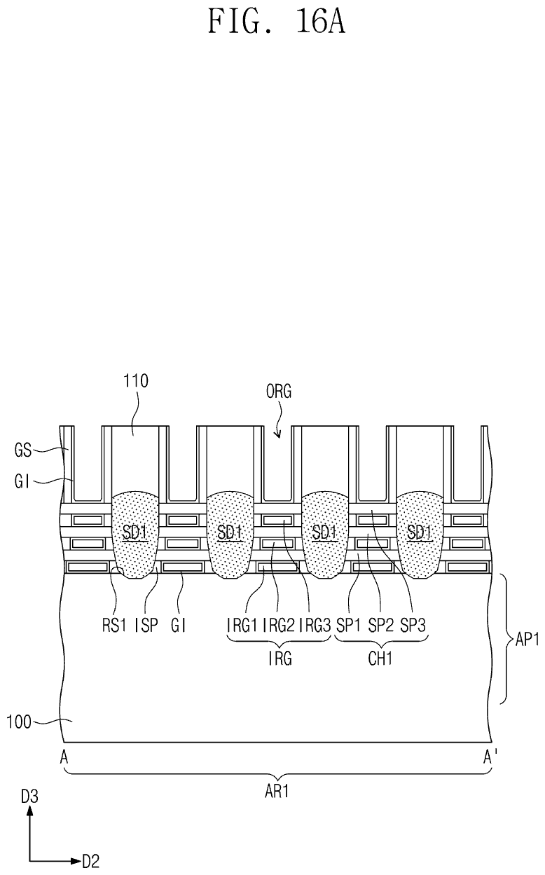

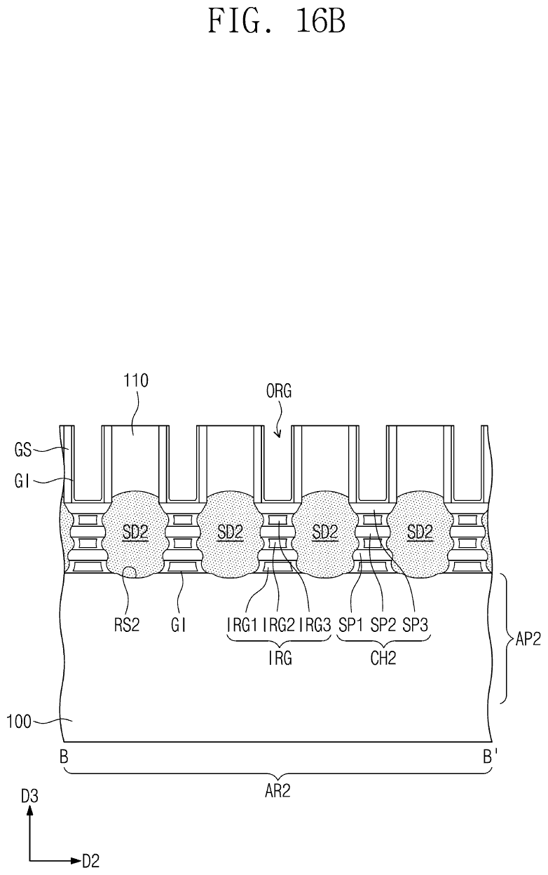

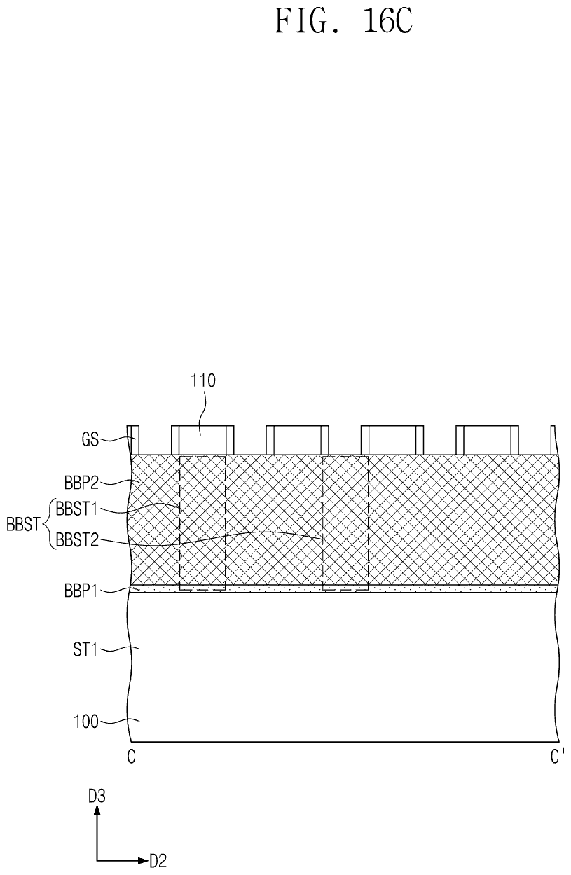

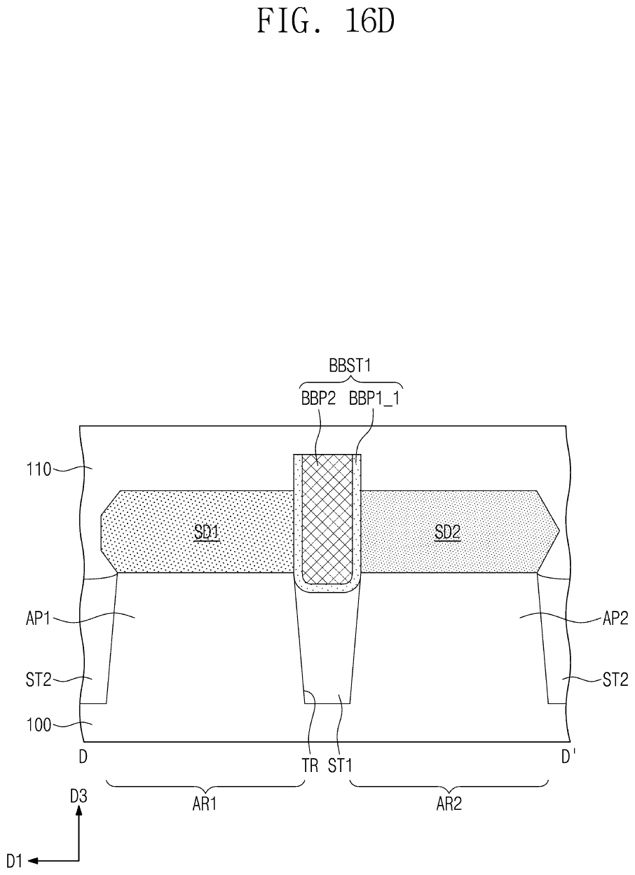

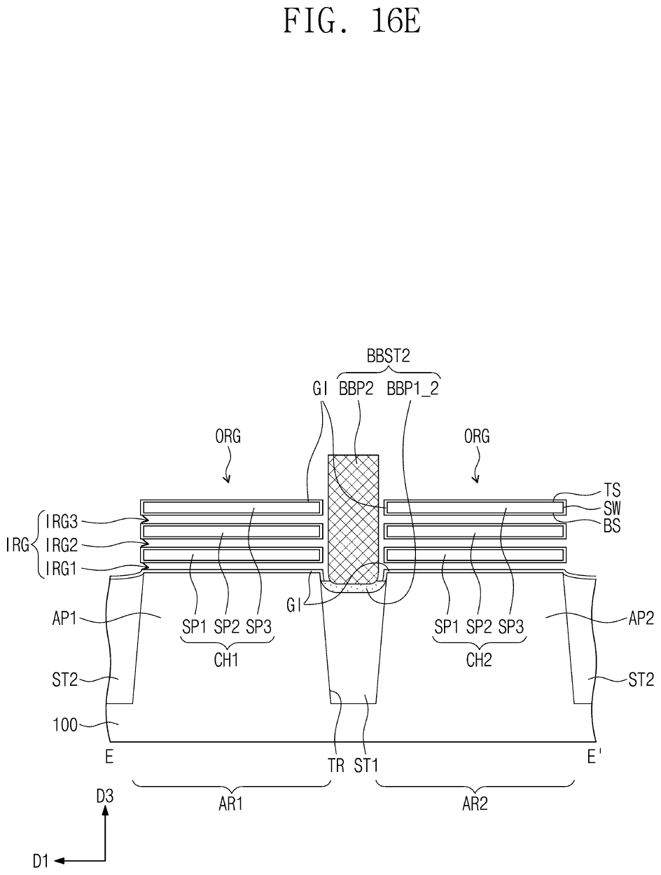

Referring to FIGS. 16A to 16E, the first interlayer insulating layer 110 may be provided on the first and second source/drain patterns SD1 and SD2, the hard mask patterns MP, and the gate spacers GS. For example, the first interlayer insulating layer 110 may be formed to cover the first and second source/drain patterns SD1 and SD2, the hard mask patterns MP, and the gate spacers GS. In an embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All the hard mask patterns MP may be removed during the planarization process. As a result, the first interlayer insulating layer 110 may be formed to have a top surface that is coplanar with the top surfaces of the sacrificial patterns PP and the top surfaces of the gate spacers GS.

In an embodiment, the exposed sacrificial patterns PP may be selectively removed. Since the sacrificial patterns PP are removed, an outer region ORG may be formed to expose the first and second channel patterns CH1 and CH2 (e.g., see FIG. 16E). The removal of the sacrificial patterns PP may include a wet etching process which is performed using an etching solution capable of selectively etching polysilicon.

The sacrificial layers SAL exposed through the outer region ORG may be selectively removed to form inner regions IRG (e.g., see FIG. 16E). For example, a process of selectively etching the sacrificial layers SAL may be performed to leave the first to third semiconductor patterns SP1, SP2, and SP3 and to remove only the sacrificial layers SAL. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the sacrificial layers SAL on the first and second active regions AR1 and AR2 may be removed. The etching process may be a wet etching process. An etchant material, which is used in the etching process, may be chosen to quickly remove the sacrificial layer SAL having a relatively high germanium concentration.

Referring back to FIG. 16E, since the sacrificial layers SAL are selectively removed, only the stacked first to third semiconductor patterns SP1, SP2, and SP3 may be left on each of the first and second active patterns AP1 and AP2. Empty regions, which are formed by removing the sacrificial layers SAL, may form first to third inner regions IRG1, IRG2, and IRG3, respectively.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring to FIG. 16E, a high-selectivity etching process may be performed on the backbone structure BBST to remove a portion of the first backbone pattern BBP1. For example, a portion of the first backbone pattern BBP1, which is in contact with the first to third semiconductor patterns SP1, SP2, and SP3, may be etched, and the first backbone pattern BBP1, which is left on the first device isolation layer ST1, may be defined as the second sub-backbone pattern BBP1_2. The high-selectivity etching process may be performed to etch a silicon oxide layer at a high etch rate. For example, the high-selectivity etching process may have a higher etch rate to silicon oxide than to silicon nitride.

The second sub-backbone pattern BBP1_2 may be extended from the bottom surface of the second backbone pattern BBP2 to a portion of the side surface of the second backbone pattern BBP2. The second sub-backbone pattern BBP1_2 may be extended to the gate insulating layer GI on the active patterns AP1 and AP2. That is, the uppermost surface of the second sub-backbone pattern BBP1_2 may be located at a level, which is lower than the uppermost surface of each of the active patterns AP1 and AP2 in the third direction D3.

Referring back to FIGS. 16A to 16E, the gate insulating layer GI may be formed on the exposed first to third semiconductor patterns SP1, SP2, and SP3. The gate insulating layer GI may be formed to enclose each of the first to third semiconductor patterns SP1, SP2, and SP3. In an embodiment, the gate insulating layer GI may be formed on a top surface TS, side surfaces SW, and a bottom surface BS of the first to third semiconductor patterns SP1, SP2, and SP3. The gate insulating layer GI may be formed in each of the first to third inner regions IRG1, IRG2, and IRG3. The gate insulating layer GI may be formed in the outer region ORG. The gate insulating layer GI may be formed on the second device isolation layer ST2 and the active pattern AP1 or AP2. An empty space or empty regions may be formed between each of the gate insulating layers GI and the second backbone pattern BBP2.

Referring back to FIGS. 16C to 16E, the backbone structure BBST may include the first backbone structure BBST1 and the second backbone structure BBST2. Each of the first and second backbone structures BBST1 and BBST2 may be defined as a portion of the backbone structure BBST. The first backbone structure BBST1 may be interposed between the first and second source/drain patterns SD1 and SD2. The second backbone structure BBST2 may be interposed between the gate electrodes GE.

Each of the first and second backbone structures BBST1 and BBST2 may include the first backbone pattern BBP1 and the second backbone pattern BBP2. The first backbone pattern BBP1 may be provided on the first device isolation layer ST1. The first backbone pattern BBP1 may have a constant thickness in the third direction D3. The first backbone pattern BBP1 may include the first sub-backbone pattern BBP1_1 and the second sub-backbone pattern BBP1_2. The second backbone pattern BBP2 may be provided on the first backbone pattern BBP1.

The first interlayer insulating layer 110 may cover the first and second source/drain patterns SD1 and SD2 and the first backbone structure BBST1. Since the first sub-backbone pattern BBP1_1 of the first backbone structure BBST1 is protected by the first interlayer insulating layer 110, it may not be removed during a high-selectivity etching process, which will be described below. That is, a top surface of the first sub-backbone pattern BBP1_1 may be substantially coplanar with a top surface of the second backbone pattern BBP2.

The first backbone structure BBST1 may include the first sub-backbone pattern BBP1_1 and the second backbone pattern BBP2 on the first sub-backbone pattern BBP1_1. The first sub-backbone pattern BBP1_1 may be in direct contact with the first and second source/drain patterns SD1 and SD2. The second backbone structure BBST2 may include the second sub-backbone pattern BBP1_2 and the second backbone pattern BBP2 on the second sub-backbone pattern BBP1_2. The second sub-backbone pattern BBP1_2 may be extended from the bottom surface of the second backbone pattern BBP2 to a portion of the side surface of the second backbone pattern BBP2.

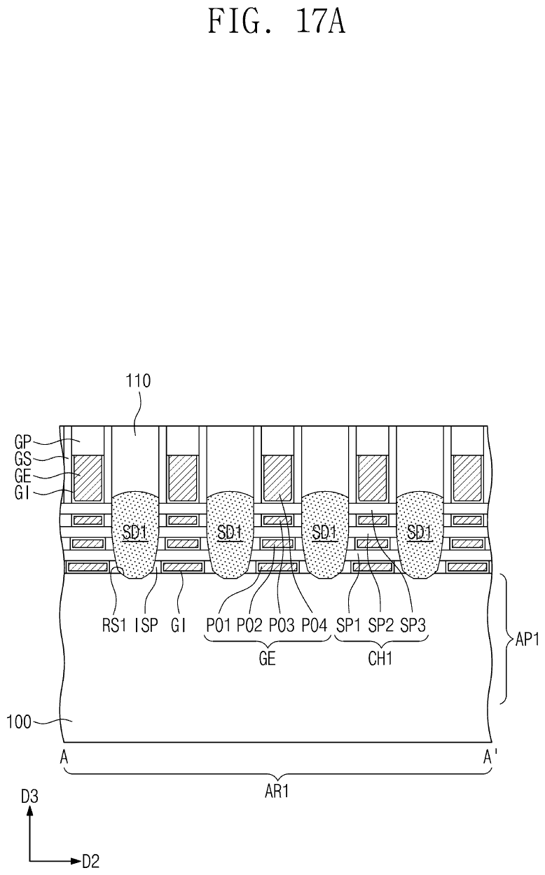

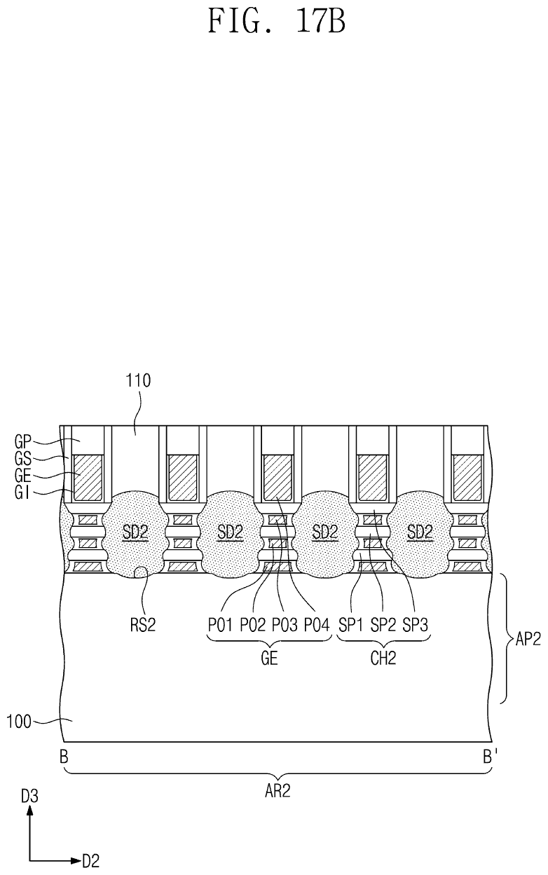

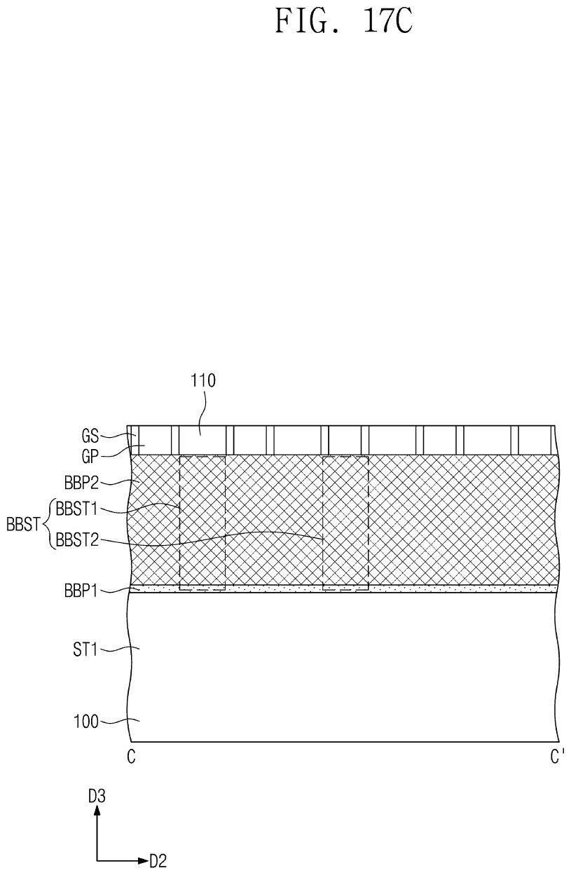

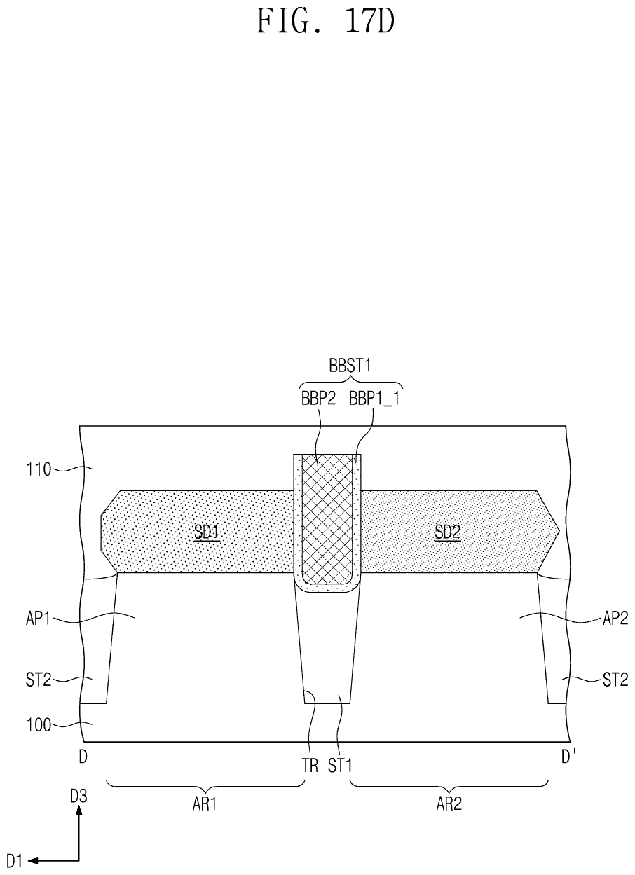

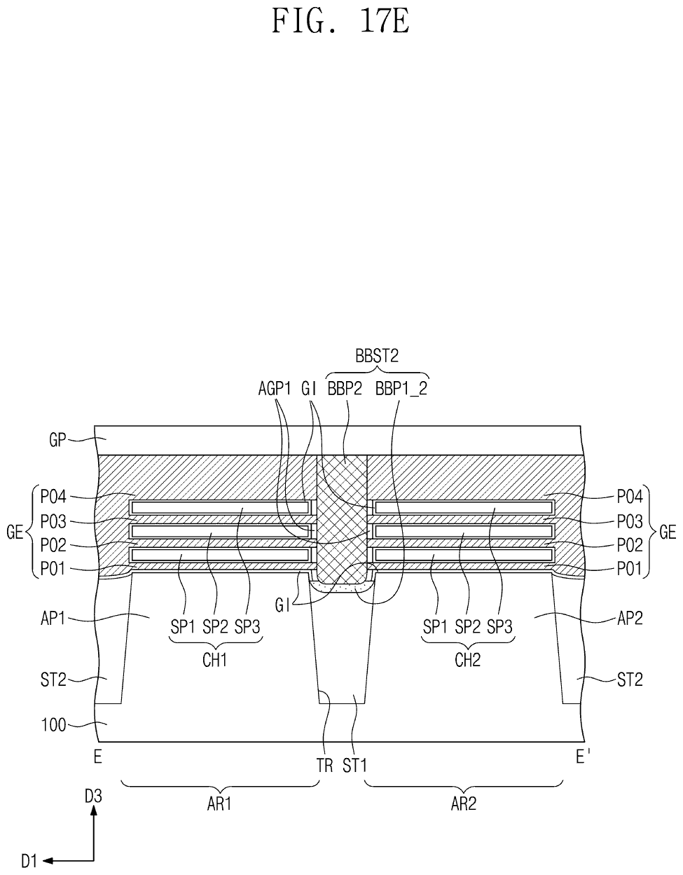

Referring to FIGS. 17A to 17E, the gate electrode GE may be formed on the gate insulating layer GI. For example, the gate electrode GE may be formed on the high-k dielectric layer HK of FIG. 5F. That is, the high-k dielectric layer HK of FIG. 5F may be formed on the gate insulating layer GI, and the gate electrode GE may be formed on the high-k dielectric layer HK of FIG. 5F. In this case, since an empty space between each of the gate insulating layers GI and the second backbone pattern BBP2 is narrow, a process margin in a process of depositing the gate electrode GE may not be sufficiently large. That is, the high-k dielectric layer HK of FIG. 5F may not be formed between each of the gate insulating layers GI and the second backbone pattern BBP2 and may be extended along the side surface of the second backbone pattern BBP2.

The gate electrode GE may include the first to third inner electrodes PO1, PO2, and PO3, which are respectively formed in the first to third inner regions IRG1, IRG2, and IRG3, and the outer electrode PO4, which is formed in the outer region ORG. The gate electrode GE may be vertically recessed to have a reduced height. The gate capping pattern GP may be formed on the recessed gate electrode GE.

For example, the formation of the gate electrode GE may include forming a first metal layer in the first to third inner regions IRG1, IRG2, and IRG3 and the outer region ORG, forming a second metal layer on the first metal layer, and performing a chemical mechanical polishing (CMP) process on the first and second metal layers using the first interlayer insulating layer 110 as a stopper. The first metal layer may include a metal nitride layer, and the second metal layer may include a metal layer with low resistance.

The formation of the first and second metal layers may include depositing the first and second metal layers to cover the gate insulating layer GI, the first interlayer insulating layer 110, and a top surface of the gate spacer GS. The CMP process on the first and second metal layers may be performed to remove the first and second metal layers using slurry.

Since the gate electrode GE is formed, an empty space or an empty region, which is confined by the high-k dielectric layer HK of FIG. 5F, may be left between each of the gate insulating layers GI and the second backbone pattern BBP2. That is, an empty space between each of the first to third semiconductor patterns SP1, SP2, and SP3 and the second backbone pattern BBP2 may be defined as the first air gap pattern AGP1. An empty space between each of the active patterns AP1 and AP2 and the second backbone pattern BBP2 may be defined as the second air gap pattern AGP2. The first and second air gap patterns AGP1 and AGP2 may be voids or seams.

Referring back to FIGS. 5A to 5F, the second interlayer insulating layer 120 may be formed on the first interlayer insulating layer 110. The second interlayer insulating layer 120 may include a silicon oxide layer. The active contacts AC may be formed to penetrate the second interlayer insulating layer 120 and the first interlayer insulating layer 110 and may be electrically connected to the first and second source/drain patterns SD1 and SD2. The gate contact GC may be formed to penetrate the second interlayer insulating layer 120 and the gate capping pattern GP and may be electrically connected to the gate electrode GE.

The formation of each of the active and gate contacts AC and GC may include forming the barrier pattern BM and forming the conductive pattern FM on the barrier pattern BM. The barrier pattern BM may be conformally formed and may include a metal layer and a metal nitride layer. The conductive pattern FM may be formed of or include a low resistance metallic material.

Referring to FIG. 5B, the active contact AC, which is connected to the second source/drain pattern SD2, may include the upper insulating pattern UIP. The upper insulating pattern UIP may prevent a short phenomenon or a coupling phenomenon between the gate contact GC and the active contact AC, which are adjacent to each other. The upper insulating pattern UIP may be formed of or include an insulating material.

The division structures DB may be respectively formed on the first and second borders BD1 and BD2 of the single height cell SHC. The division structure DB may penetrate the second interlayer insulating layer 120 and the gate electrode GE and may be extended into the active pattern AP1 or AP2. The division structure DB may be formed of or include an insulating material (e.g., silicon oxide or silicon nitride). In an embodiment, the division structure DB may include a metallic material.

The third interlayer insulating layer 130 may be formed on the active and gate contacts AC and GC. The first metal layer M1 may be formed in the third interlayer insulating layer 130. The first metal layer M1 may include the first interconnection line M1_I, which is electrically connected to at least one of the active and gate contacts AC and GC. The fourth interlayer insulating layer 140 may be formed on the third interlayer insulating layer 130. The second metal layer M2 may be formed in the fourth interlayer insulating layer 140.

In a three-dimensional field effect transistor according to an embodiment of the disclosure, by forming an air gap pattern between a channel pattern and a backbone structure, it may be possible to increase a stress exerted on the channel pattern. That is, the stress may increase the mobility of carriers in the channel pattern. In addition, due to the presence of the air gap pattern, the parasitic capacitance issue may be reduced. Accordingly, the electrical characteristics of the semiconductor device may be improved.

In a three-dimensional field effect transistor according to an embodiment of the disclosure, by forming an air layer in a backbone structure, it may be possible to reduce an electrostatic capacitance in the backbone structure. That is, it may be possible to reduce a parasitic capacitance, which may be caused by the backbone structure, and improve performance of a cell including a transistor. Accordingly, the electrical characteristics of the semiconductor device may be improved.

In a three-dimensional field effect transistor according to an embodiment of the disclosure, by forming a backbone structure between a pair of NMOSFET and PMOSFET regions, it may be possible to reduce an occupying area of a unit cell, which constitutes a logic device, in a substrate. That is, it may be possible to increase the number of the unit cells, which are formed on the substrate, and thereby to increase the integration density of the semiconductor device.

While example embodiments of the disclosure have been particularly shown and described, it will be understood by one of ordinary skill in the art that variations in form and detail may be made therein without departing from the spirit and scope of the attached claims.

What is claimed is:

1. A semiconductor device comprising:
a substrate comprising an active pattern;
a channel pattern on the active pattern, the channel pattern comprising a plurality of semiconductor patterns vertically stacked and spaced apart from each other;
a source/drain pattern connected to the plurality of semiconductor patterns;
a gate electrode is provided on a top surface, a first side surface, and a bottom surface of each of the plurality of semiconductor patterns;
a backbone structure on a side surface of the gate electrode; and
a first air gap pattern between the backbone structure and each of the plurality of semiconductor patterns,
wherein the first air gap pattern is provided on a second side surface of each of the plurality of semiconductor patterns.

2. The semiconductor device of claim 1, wherein the first air gap pattern is a void or seam.

3. The semiconductor device of claim 1, further comprising a gate insulating layer provided on each of the plurality of semiconductor patterns,
wherein the first air gap pattern is provided between the gate insulating layer and the backbone structure.

4. The semiconductor device of claim 1, wherein a top surface of the backbone structure is substantially coplanar with a top surface of the gate electrode.

5. The semiconductor device of claim 1, further comprising a device isolation layer defining the active pattern,
wherein the backbone structure comprises:
a first sub-backbone pattern on the device isolation layer; and
a second backbone pattern on the first sub-backbone pattern,
wherein the first sub-backbone pattern extends from a bottom surface of the second backbone pattern to a side surface of the second backbone pattern.

6. The semiconductor device of claim 5, wherein the first sub-backbone pattern extends from the bottom surface of the second backbone pattern to a portion of the side surface of the second backbone pattern.

7. The semiconductor device of claim 5, wherein an uppermost surface of the first sub-backbone pattern is lower than an uppermost surface of the active pattern.

8. The semiconductor device of claim 5, further comprising a second air gap pattern provided between the second backbone pattern and the active pattern,
wherein each of the first air gap pattern and second air gap pattern is a void or seam.

9. The semiconductor device of claim 8, further comprising:
a first gate insulating layer provided on each of the plurality of semiconductor patterns; and
a high-k dielectric layer provided between the first gate insulating layer and the gate electrode,
wherein the first air gap pattern is surrounded by the high-k dielectric layer, the first gate insulating layer, and the second backbone pattern.

10. The semiconductor device of claim 9, further comprising a second gate insulating layer on a top surface of the active pattern,
wherein the second air gap pattern is surrounded by the high-k dielectric layer, the second gate insulating layer, the first sub-backbone pattern, and the second backbone pattern.

11. The semiconductor device of claim 5, wherein the first sub-backbone pattern comprises an insulating material having a different etch rate than the second backbone pattern.

12. The semiconductor device of claim 10, wherein the first sub-backbone pattern comprises silicon oxide, and
the second backbone pattern comprises silicon nitride.

13. A semiconductor device comprising:
a substrate comprising a first active pattern and a second active pattern;
a first channel pattern on the first active pattern and a second channel pattern on the second active pattern, each of the first channel pattern and second channel pattern comprising a plurality of semiconductor patterns, which are vertically stacked and spaced apart from each other;
a first source/drain pattern connected to the first channel pattern and a second source/drain pattern connected to the second channel pattern;
a first gate electrode on the first channel pattern and a second gate electrode on the second channel pattern; and
a backbone structure provided between the first gate electrode and the second gate electrode,
wherein the backbone structure comprises:
a liner pattern on a side surface of each of the first gate electrode and the second gate electrode; and
a backbone pattern provided in a space defined by the liner pattern,
wherein the liner pattern contacts the plurality of semiconductor patterns.

14. The semiconductor device of claim 13, wherein each of the first source/drain pattern and the second source/drain pattern is provided on an NMOSFET region and comprises n-type impurities, and
wherein the liner pattern comprises one or more of SiO₂, BPSG, or SiOC.

15. The semiconductor device of claim 13, wherein each of the first source/drain patterns and the second source/drain pattern is provided on a PMOSFET region and comprises p-type impurities, and
wherein the liner pattern comprises one or more of Si₃N₄, SiC, AlN, or Al₂O₃.

16. The semiconductor device of claim 13, further comprising a device isolation layer defining the first active pattern and the second active pattern,
wherein the liner pattern extends from the side surface of the first gate electrode to the side surface of the second gate electrode via a top surface of the device isolation layer, and
a top surface of the liner pattern, a top surface of the backbone pattern, and a top surface of each of the first gate electrode and the second gate electrode are substantially coplanar with each other.

17. The semiconductor device of claim 13, further comprising:
a gate insulating layer on each of the plurality of semiconductor patterns; and
a high-k dielectric layer provided between the gate insulating layer and each of the first gate electrode and the second gate electrode,
wherein the liner pattern contacts the plurality of semiconductor patterns, the gate insulating layer, and the high-k dielectric layer.

18. A semiconductor device comprising:
a substrate comprising a first active pattern and a second active pattern;
a device isolation layer defining each of the first active pattern and the second active pattern;
a first channel pattern on the first active pattern and a second channel pattern on the second active pattern, each of the first channel pattern and the second channel pattern comprising a plurality of semiconductor patterns, which are stacked and spaced apart from each other;
a first source/drain pattern connected to the first channel pattern and a second source/drain pattern connected to the second channel pattern;
a first gate electrode on the first channel pattern and a second gate electrode on the second channel pattern, each of the first gate electrode and the second gate electrode comprising inner electrodes provided between adjacent ones of the plurality of semiconductor patterns and an outer electrode provided on an uppermost semiconductor pattern among of the plurality of semiconductor patterns;
a first backbone structure and a second backbone structure on the device isolation layer, the first backbone structure being provided between the first source/drain pattern and second source/drain pattern, the second backbone structure being provided between the first gate electrode and the second gate electrode;
a gate insulating layer interposed between the first gate electrode, the second gate electrode and each of the first channel pattern and second channel pattern;
a first air gap pattern provided between the gate insulating layer and the second backbone structure;
a gate spacer on a side surface of each of the first gate electrode and the second gate electrode;
a gate capping pattern on a top surface of each of the first gate electrode and the second gate electrode;
an interlayer insulating layer provided on the first source/drain pattern, the second source/drain pattern and the gate capping pattern;
an active contact provided to penetrate the interlayer insulating layer and electrically connected to each of the first source/drain pattern, the second source/drain pattern;
a first gate contact provided to penetrate the gate capping pattern on the first gate electrode and the interlayer insulating layer and electrically connected to the first gate electrode;
a second gate contact provided to penetrate the gate capping pattern on the second gate electrode and the interlayer insulating layer and electrically connected to the second gate electrode
a first metal layer on the interlayer insulating layer, the first metal layer comprising a first interconnection line electrically connected to the active contact and the first gate contact and the second gate contact; and
a second metal layer on the first metal layer, the second metal layer comprising a second interconnection line electrically connected to the first metal layer,
wherein the first backbone structure comprises:
a first sub-backbone pattern on the device isolation layer; and
a second backbone pattern filling a space defined by the first sub-backbone pattern,
wherein the second backbone structure comprises:
a second sub-backbone pattern on the device isolation layer; and
the second backbone pattern on the second sub-backbone pattern,
wherein an uppermost surface of the first sub-backbone pattern is located higher than an uppermost surface of the second sub-backbone pattern.

19. The semiconductor device of claim 18, further comprising a second air gap pattern provided between each of the first active pattern, and the second active pattern and the second backbone pattern,
wherein the first air gap pattern is provided between the gate insulating layer and the second backbone pattern, and
wherein each of the first air gap pattern and the second air gap pattern is a void or seam.

20. The semiconductor device of claim 18, wherein each of the first sub-backbone pattern and second sub-backbone pattern comprises an insulating material having a different etch rate than the second backbone pattern,
each of the first sub-backbone pattern and second sub-backbone pattern comprises silicon oxide, and
wherein the second backbone pattern comprises silicon nitride.
